(19) United States
(12) Patent Application Publication
(10) Pub. No.: US 2006/0216867 A1
(43) Pub. Date: Sep. 28, 2006

(54) Method of manufacturing a semiconductor device

(76) Inventors: Youichi Kawata, Higashiyamato (JP); Bunshi Kuratomi, Kodaira (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/365,503

(22) Filed: Mar. 2, 2006

(30) Foreign Application Priority Data
Mar. 22, 2005 (JP) 2005-081453

(51) Int. Cl. H01L 21/00

(52) U.S. Cl. 438/124; 438/126

(57) ABSTRACT

In the manufacture of a semiconductor device, a molding die is used having a resin sealing member forming section positioned over the main surface of a wiring substrate so as to cover a semiconductor chip mounted on the wiring substrate, and a resin flowing path crossing one side of the wiring substrate from the outside of the wiring substrate and communicating with the resin sealing member forming section, when the wiring substrate is arranged between an upper die and a lower die. A method of manufacturing a semiconductor device includes a step of forming a resin sealing member, that seals the semiconductor chip mounted on the wiring substrate with resin, by injecting resin into the resin sealing member forming section through the resin flowing path. The resin flowing path has a first portion positioned at the outside of the wiring substrate and a second portion communicating with the first portion and the resin sealing member forming section and positioned over the main surface of the wiring substrate. The height of the second portion from the main surface of the wiring substrate is lower than that of the first portion.

### CROSS-REFERENCE TO RELATED APPLICATION

The present application claims priority from Japanese patent application No. 2005-081453 filed on Mar. 22, 2005, the content of which is hereby incorporated by reference into this application.

### BACKGROUND OF THE INVENTION

The present invention relates to a technique of manufacturing a semiconductor device, and more particularly to a technique effective for applying a semiconductor device wherein a semiconductor chip mounted over a substrate is sealed with resin by a transfer molding method.

In a manufacture of a semiconductor device such as a BGA (Ball Grid Array) type or CSP (Chip Size Package) type, a mold array package is adopted, for example. In the mold array package, a multi-wiring substrate (multi-chip bonded substrate) having plural device forming regions (device regions), that are arranged on a plane in a matrix, is used, wherein plural semiconductor chips mounted over the main surface of the wiring substrate so as to correspond to each device forming region are resin-sealed by one resin sealing member. Specifically, the multi-wiring substrate over which plural semiconductor chips are mounted so as to correspond to each device forming region is positioned between an upper die and lower die of a molding die and clamped, and then, melted thermosetting resin is injected into a sealing cavity (resin sealing member forming section), whereby the plural semiconductor chips mounted so as to correspond to each device forming region are sealed by the resin together at a time.

The manufacturing technique of a semiconductor device using the mold array package described above is disclosed in, for example, Japanese Unexamined Patent Application No. 2003-109983 (Patent Reference 1). The same reference 1 also discloses the technique wherein “agate 22 (resin member), runner 23 (resin member) and cull 24 (resin member) can be separated from a molded piece as unaffected by the adhesiveness between a ceramic substrate 20 and a resin 27 by forming a gate break point at the end face of the ceramic substrate 20, and hence, the crack caused on the ceramic substrate 20 can be prevented”.

[Patent Reference 1]

Japanese Unexamined Patent Application No. 2003-109983

### SUMMARY OF THE INVENTION

In a transfer molding technique, a molding die provided with a pot, cull, runner, resin injection gate, sealing cavity, and the like is used. Thermosetting resin is injected into the sealing cavity through the pot, cull, runner and resin injection gate of the molding die. Therefore, the resin member (unnecessary resin member) is formed from the thermosetting resin remaining on the cull, runner, or the like, separate from the resin sealing member formed at the sealing cavity. This resin member is formed integral with the resin sealing member at the sealing cavity. Accordingly, a process for separating the resin member from the resin sealing member is incorporated after the resin sealing member is formed (after the resin-sealing) in the manufacture of a semiconductor device using the transfer molding technique. In this process, the resin sealing member and the resin member are separated from each other at the position corresponding to the resin injection gate of the molding die, so that this process is generally called a gate breaking process.

The gate breaking process is performed also in the manufacture of a semiconductor device using the mold array package. FIGS. 33(a) and 33(b) are sectional views showing a gate breaking process in the manufacture of a semiconductor device using the conventional mold arraypackage. In the figure, numeral 100 denotes a multi-wiring substrate, 101 denotes a semiconductor chip, 102 denotes a resin sealing member, 103 denotes a resin member (unnecessary resin member) formed integrally with the resin sealing member 102 by the thermosetting resin remaining on the cull, runner or the like of the molding die, 104 denotes a separation portion (a portion corresponding to the resin injection gate of the molding die), 105 denotes a stage, and 106 denotes a package holding member.

In the gate breaking process, the multi-wiring substrate 100 placed on the stage 105 is firstly fixed by the package holding member 106 as shown in FIG. 33(a), and then, the resin member 103 is bent in the thickness direction of the multi-wiring substrate 103 with respect to the resin sealing member 102 such that bending stress is concentrated on the separation portion 104, resulting in that a crack is produced on the separation portion 104. Thus, the resin sealing member 102 and the resin member 103 are separated from each other at the separation portion 104.

However, the resin member 103 is integrated with the resin sealing member 102 crossing one side of the multi-wiring substrate 100, so that a part thereof is adhered on the multi-substrate 100. Therefore, when the resin member 103 is bent with respect to the resin sealing member 102, bending stress is also exerted on the multi-wiring substrate 100. If the rigidity of the substrate is great (high), the resin member is separated from the substrate, but if the rigidity of the substrate is small (low), the resin member is not separated from the substrate, with the result that the substrate is bent. In recent years, the substrate tends to be made thin as a size of a semiconductor device is reduced. The thinner the substrate is made, the smaller the rigidity of the substrate becomes. As a result, deficiency is likely to occur with the reduced size of the substrate, such as breakdown of the multi-wiring substrate 100, as shown in FIG. 33(b). Although different depending upon the condition such as a plane size of the substrate, a length of the resin member extending on the substrate, or the like, the breakdown of the substrate does not occur with the thickness of 0.2 mm, but the substrate is broken down with the thickness of 0.13 mm according to the research made by the present inventors. A countermeasure should be taken, since the breakdown of the substrate leads to the reduction in production yield of a semiconductor device.

The Patent Reference 1 (Japanese Unexamined Patent Application No. 2003-109983) discloses in the column [0036] to [0038] a configuration of a molding die in which “a first cavity (sealing cavity) corresponding to a semiconductor product and one or more projecting second cavities formed at the end face of the first cavity in the widthwise direction of the ceramic substrate 20 are provided, and a gate break point is formed at the end face of the ceramic substrate 20 for preventing a crack of the ceramic substrate 20”. However, the technique disclosed in the Patent Reference 1 entails the following problem, since the thickness of the resin 21 (first resin) and the thickness of the projecting resin 28 (second resin) extending toward the gate side communicating with the resin 21 are equal to each other, in other words, the thickness of the first cavity and the thickness of the second cavity are equal to each other.

(1) The multi-wiring substrate 100 subject to the gate breaking process is transported to the next bump-mounting process along a pair of transporting rails spaced from each other. The multi-wiring substrate 100 has a rectangular plane shape in general, so that the multi-wiring substrate 100 is transported along the direction of the long side. Specifically, as shown in FIG. 34, a groove 111 is formed at each of a pair of transporting rails 110 so as to be opposite to each other. One long side of the multi-wiring substrate 100 is fitted into the groove 111 of one of the transporting rails 110 and the other long side is fitted into the groove 111 of the other of the transporting rails 110. In the bump-mounting process, bumps are formed on the back surface 100y of the multi-wiring substrate 100, so that the multi-wiring substrate 100 is transported with the back surface 100y, that is the reverse side of the main surface 100x having the resin sealing member 102 formed thereon, facing upward.

When the technique disclosed in the Patent Reference 1 is used, the projecting resin member (corresponding to the second resin 28 in the Patent Reference 1) 107 that is integrated with the resin sealing member (corresponding to the first resin 21 in the Patent Reference 1) 102 is formed only at one long side of the multi-wiring substrate 100 as shown in FIG. 35. When the multi-wiring substrate 100 described above is transported to the next bump-mounting process along a pair of transporting rails 110, the multi-wiring substrate 100 is slanted against the pair of transporting rails 110 as shown in FIG. 35, so that the poor transportation is likely to occur such as the substrate is jammed. The rate of the poor transportation of the substrate becomes high as the angle of inclination of the multi-wiring substrate 100 to the pair of transporting rails 110 becomes great. In the Patent Reference 1, the height of the projecting resin member 107 is made equal to the height of the resin sealing member 101, so that the angle of inclination of the multi-wiring substrate 100 to the pair of transporting rails 110 is great, that leads to a high rate of the poor transportation of the substrate. The poor transportation of the substrate described above leads to the reduction in productivity of a semiconductor device. Accordingly, some countermeasure should be taken.

(2) In the mold array package, the ratio of the plane area to the height (thickness) of the sealing cavity is extremely great, so that the mold release for releasing the resin sealing member from the cavity becomes difficult. In view of this, a laminate method is used in the mold array package. In the laminate method, a film is adhered onto the inner face of the cull, runner, cavity and the like of the molding die, whereby the resin sealing member is formed by injecting the thermosetting resin into the cavity through the pot, cull, runner and resin injection gate.

In the mold array package, the ratio of the plane area to the thickness (height) of the cavity is extremely great. Therefore, the thermosetting resin should be rapidly and uniformly injected during a limited time from when the curing of the thermosetting resin is started to when its fluidity is reduced. In view of this, the mold array package uses a molding die having plural resin injection gates along one long side of the cavity (along one long side of the multi-wiring substrate).

When the technique disclosed in the Patent Reference 1 is adopted, plural projecting cavities (corresponding to the second cavity in the Patent Reference 1) are arranged at one long side of the sealing cavity (corresponding to the first cavity in the Patent Reference 1) along the same long side. In case where the laminate molding is performed by using the molding die described above, the film is also adhered onto the inner face of the projecting cavities. However, the width of the projecting cavity is extremely narrow compared to the width of the sealing cavity, so that wrinkles are likely to occur on the film over the projecting cavity to the sealing cavity. Further, plural projecting cavities are provided, whereby wrinkles are more likely to occur due to the irregularity by the plural projecting cavities. The rate of occurrence of wrinkles on the film increases as the height (thickness) of the projecting cavity increases. In the Patent Reference 1, the height of the projecting cavity is equal to the height of the sealing cavity, with the result that the rate of occurrence of wrinkles is high. The wrinkles on the film leads to a poor formation of the resin sealing member, that leads to the reduction in production yield of a semiconductor device. Therefore, some countermeasure should be taken.

The above-mentioned problems occur in a discrete molding method wherein a multi-wiring substrate having plural device forming regions is used, and plural semiconductor chips mounted over the main surface of the multi-wiring substrate so as to correspond to each device forming region are sealed with resin for every device forming region.

An object of the present invention is to provide a technique capable of improving production yield of a semiconductor device.

Another object of the present invention is to provide a technique capable of enhancing productivity of a semiconductor device.

The foregoing and other objects, features, aspects and advantages of the present invention will become more apparent from the following detailed description of the present invention when taken in conjunction with the accompanying drawings.

A brief description will be given to the outline of the representative aspects of the present invention disclosed in the present application.

(1) A method of manufacturing a semiconductor device comprises steps of: preparing a wiring substrate having a semiconductor chip mounted over its main surface; preparing, when the wiring substrate is arranged between an upper die and a lower die, a molding die having a resin sealing member forming section (sealing cavity) positioned over the main surface of the wiring substrate so as to cover the semiconductor chip mounted over the wiring substrate, and a resin flowing path (runner) crossing one side of the wiring substrate from the outside of the wiring substrate to communicate with the resin sealing member forming section; forming a resin sealing member that resin-seals the semiconductor chip mounted over the wiring substrate, arranged between the upper die and the lower die of the molding die, by injecting resin into the resin sealing member forming section through the resin flowing path; and applying bending stress to a resin member, that is formed integrally with the resin sealing member from the remaining resin in the resin flowing path, in the widthwise direction of the wiring substrate, thereby producing a crack on the resin member, wherein the resin flowing path has a first portion positioned at the outside of the wiring substrate and a second portion communicating with the first portion and the resin sealing member forming section and positioned over the main surface of the wiring substrate, and wherein the height of the second portion from the main surface of the wiring substrate is lower than that of the first portion.

(2) A method of manufacturing a semiconductor device comprises steps of: preparing a wiring substrate having a semiconductor chip mounted over its main surface; preparing, when the wiring substrate is arranged between an upper die and a lower die, a molding die having a resin sealing member forming section positioned over the main surface of the wiring substrate so as to cover the semiconductor chip mounted over the wiring substrate, a first resin flowing path crossing a first side of the wiring substrate from the outside of the wiring substrate to communicate with the resin sealing member forming section, and a second resin flowing path positioned over the main surface of the wiring substrate at a second side of the wiring substrate that is opposite to the first side thereof to communicate with the resin sealing member forming section; forming a resin sealing member that resin-seals the semiconductor chip mounted over the wiring substrate, arranged between the upper die and the lower die of the molding die, by injecting resin into the resin sealing member forming section through the first resin flowing path; and applying bending stress to a first resin member, that is formed integrally with the resin sealing member from the remaining resin in the first resin flowing path, in the widthwise direction of the wiring substrate, thereby producing a crack on the first resin member, wherein the first resin flowing path of the molding die has a first portion positioned at the outside of the wiring substrate and a second portion communicating with the first portion and the resin sealing member forming section and positioned over the main surface of the wiring substrate, and wherein the height of the second portion of the first resin flowing path and the height of the second resin flowing path from the main surface of the wiring substrate are lower than that of the first portion of the first resin flowing path and the resin sealing member forming section.

(3) A method of manufacturing a semiconductor device comprises steps of: preparing a wiring substrate having a semiconductor chip mounted over its main surface; preparing, when the wiring substrate is arranged between an upper die and a lower die, a molding die having a resin sealing member forming section positioned over the main surface of the wiring substrate so as to cover the semiconductor chip mounted over the wiring substrate, and a resin flowing path crossing one side of the wiring substrate from the outside of the wiring substrate to communicate with the resin sealing member forming section; and forming a resin sealing member that resin-seals the semiconductor chip mounted over the wiring substrate, arranged between the upper die and the lower die of the molding die, by injecting resin into the resin sealing member forming section through the resin flowing path with a resin sheet adhered onto the inner face of the resin flowing path and the inner face of the resin sealing member forming section, wherein the height of the resin flowing path from the main surface of the wiring substrate is lower than that of the resin sealing member forming section at the main surface of the wiring substrate.

The aforesaid techniques (1) and (2) can prevent the damage on the wiring substrate, thereby being capable of improving production yield of a semiconductor device.

The aforesaid techniques (1) and (2) can enhance the stability in the transportation of the wiring substrate, thereby being capable of enhancing productivity of a semiconductor device.

The aforesaid techniques (1), (2) and (3) can prevent the poor formation of the resin sealing member caused by the wrinkles on the film, thereby being capable of improving production yield of a semiconductor device.

A brief description will be given to the effects obtained by the representative aspects of the present invention disclosed in the present application.

According to the present invention, production yield of a semiconductor device can be improved.

According to the present invention, productivity of a semiconductor device can be enhanced.

### BRIEF DESCRIPTION OF THE DRAWINGS

FIG. 1(a) and FIG. 1(b) are views showing an internal structure of a semiconductor device according to an embodiment 1 of the present invention, in which FIG. 1(a) is a plan view and FIG. 1(b) is a sectional view taken along a line a-a line in FIG. 1(a);

FIG. 2(a) and FIG. 2(b) are views showing a configuration of a multi-wiring substrate (multi-chip bonded substrate) used for manufacturing the semiconductor device according to the embodiment 1 of the present invention, in which FIG. 2(a) is a plan view and FIG. 2(b) is a sectional view;

FIG. 3(a) and FIG. 3(b) are views showing a state in which semiconductor chips are mounted on the multi-wiring substrate in the manufacture of the semiconductor device according to the embodiment 1 of the present invention, in which FIG. 3(a) is a plan view and FIG. 3(b) is a sectional view;

FIG. 4 is a perspective plan view showing a state in which the multi-wiring substrate is clamped by a molding die in the manufacture of the semiconductor device according to the embodiment 1 of the present invention;

FIG. 5 is a sectional view taken along a line b-b in FIG. 4:

FIG. 6 is a sectional view taken along a line c-c in FIG. 4;

FIG. 7 is an enlarged sectional view showing a part (leftward section in the figure) of FIG. 5;

FIG. 8 is an enlarged sectional view showing a part (rightward section in the figure) of FIG. 5;

FIG. 9 is a perspective plan view showing a state in which resin is injected into a sealing cavity (resin sealing member forming section) of the molding die to form a resin sealing member in the manufacture of the semiconductor device according to the embodiment 1 of the present invention;

FIG. 10 is a sectional view taken along a line d-d in FIG. 9;

FIG. 11 is a sectional view showing a state in which the multi-wiring substrate is removed from the molding die after the completion of the resin sealing process in the manufacture of the semiconductor device according to the embodiment 1 of the present invention;

FIG. 12(a) and FIG. 12(b) are sectional views for explaining a breaking process in the manufacture of the semiconductor device according to the embodiment 1 of the present invention;

FIG. 13(a) and FIG. 13(b) are views for explaining a bump-mounting process in the manufacture of the semiconductor device according to the embodiment 1 of the present invention, in which FIG. 13(a) is a plan view and FIG. 13(b) is a sectional view;

FIG. 14 is a sectional view for explaining a dicing process in the manufacture of the semiconductor device according to the embodiment 1 of the present invention;

FIG. 15 is a plan view showing a transporting state of the multi-wiring substrate in the manufacture of the semiconductor device according to the embodiment 1 of the present invention;

FIG. 16 is a sectional view taken along a line e-e in FIG. 15;

FIG. 17 is a sectional view showing a transporting state of the multi-wiring substrate in the manufacture of the semiconductor device according to the modified example 1 of the embodiment 1 of the present invention;

FIG. 18 is a sectional view showing a state in which the multi-wiring substrate is clamped by the molding die in the manufacture of the semiconductor device according to the modified example 2 of the embodiment 1 of the present invention;

FIG. 19 is a sectional view showing a state in which the multi-wiring substrate is clamped by the molding die in the manufacture of the semiconductor device according to the modified example 3 of the embodiment 1 of the present invention;

FIG. 20 is a perspective plan view showing a state in which the multi-wiring substrate is clamped by the molding die in the manufacture of the semiconductor device according to an embodiment 2 of the present invention;

FIG. 21 is a sectional view taken along a line f-f in FIG. 20;

FIG. 22 is an enlarged sectional view of apart (rightward section in the figure) of FIG. 21;

FIG. 23 is a sectional view showing a state in which the multi-wiring substrate is removed from the molding die after the completion of the resin sealing process in the manufacture of the semiconductor device according to the embodiment 2 of the present invention;

FIG. 24(a) and FIG. 24(b) are sectional views for explaining a breaking process in the manufacture of the semiconductor device according to the embodiment 2 of the present invention;

FIG. 25(a) and FIG. 25(b) are views showing an internal structure of a semiconductor device according to an embodiment 3 of the present invention, in which FIG. 25(a) is a perspective plan view and FIG. 25(b) is a sectional view taken along a line g-g in FIG. 25(a);

FIG. 26(a) and FIG. 26(b) are views showing a configuration of a multi-wiring substrate used for manufacturing the semiconductor device according to the embodiment 3 of the present invention, in which FIG. 26(a) is a plan view and FIG. 26(b) is a sectional view;

FIG. 27 is a perspective plan view showing a state in which the multi-wiring substrate is clamped by a molding die in the manufacture of the semiconductor device according to the embodiment 3 of the present invention;

FIG. 28 is a sectional view taken along a line h-h in FIG. 27;

FIG. 29 is a sectional view taken along a line i-i in FIG. 27;

FIG. 30 is a perspective plan view showing a state in which resin is injected into a sealing cavity (resin sealing member forming section) of the molding die to form a resin sealing member in the manufacture of the semiconductor device according to the embodiment 3 of the present invention;

FIG. 31 is a sectional view taken along a line j-j in FIG. 30;

FIG. 32(a) and FIG. 32(b) are sectional views for explaining a breaking process in the manufacture of the semiconductor device according to the embodiment 3 of the present invention;

FIG. 33(a) and FIG. 33(b) are sectional views showing a gate breaking process in the manufacture of a semiconductor device using a conventional mold array package;

FIG. 34 is a sectional view showing a transporting state of the multi-wiring substrate in the manufacture of a semiconductor device using the conventional mold array package; and

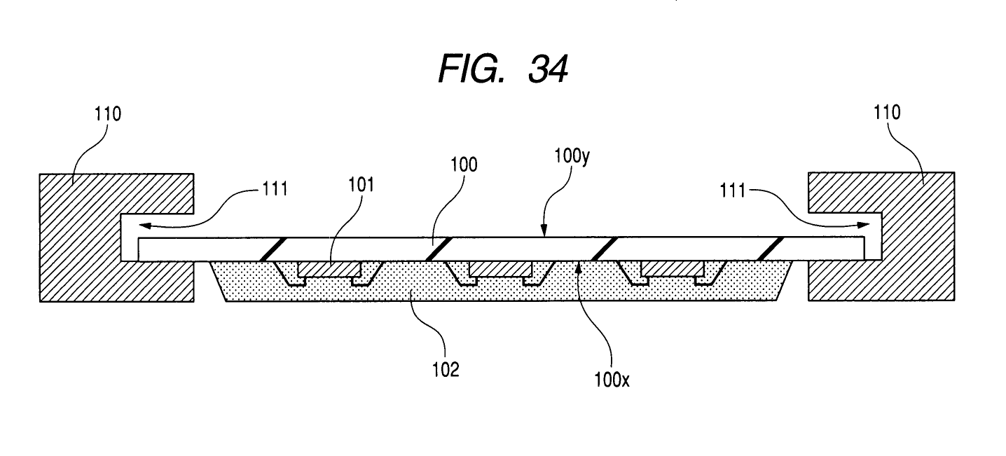

FIG. 35 is a sectional view showing a transporting state of the multi-wiring substrate in the manufacture of a semiconductor device using the conventional mold array package.

### DETAILED DESCRIPTION OF THE PREFERRED EMBODIMENTS

Embodiments of the present invention will be explained in detail with reference to drawings. In all drawings for explaining the embodiments, elements having identical functions are identified by the same reference numerals and duplicate descriptions of them are omitted.

### Embodiment 1

The embodiment 1 explains a semiconductor device using a collective transfer molding method.

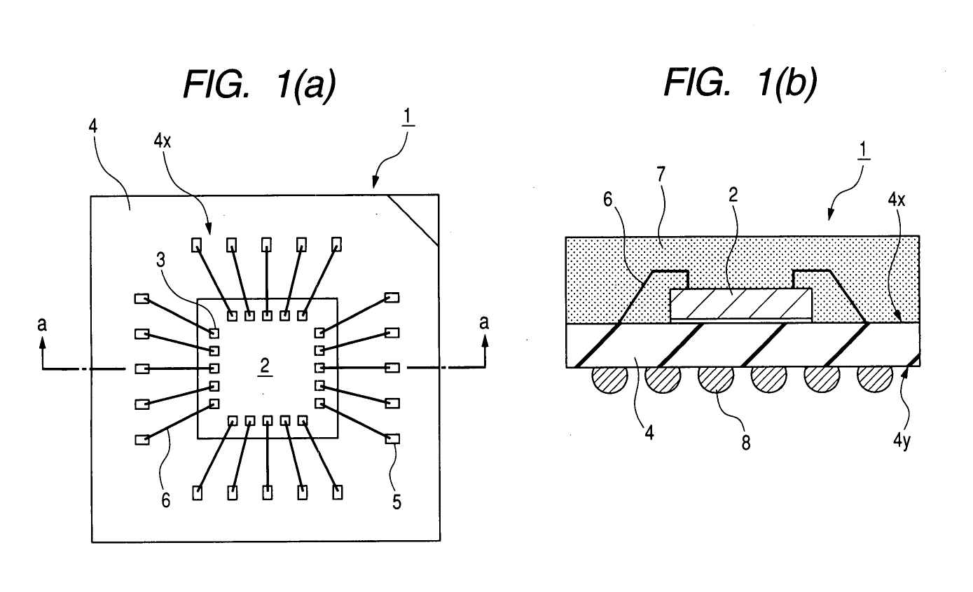

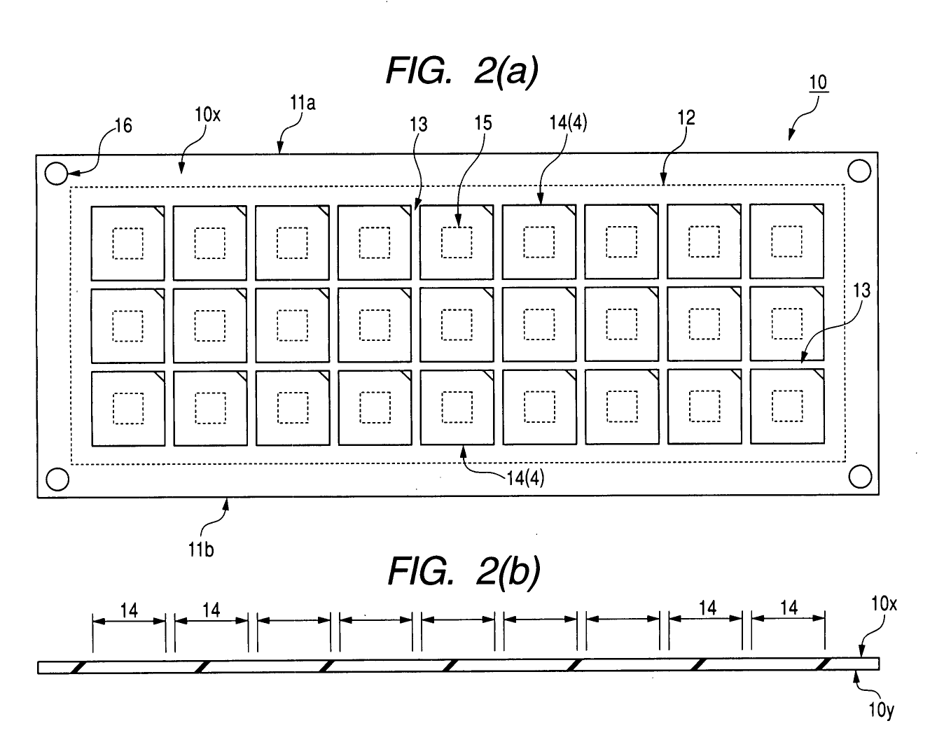

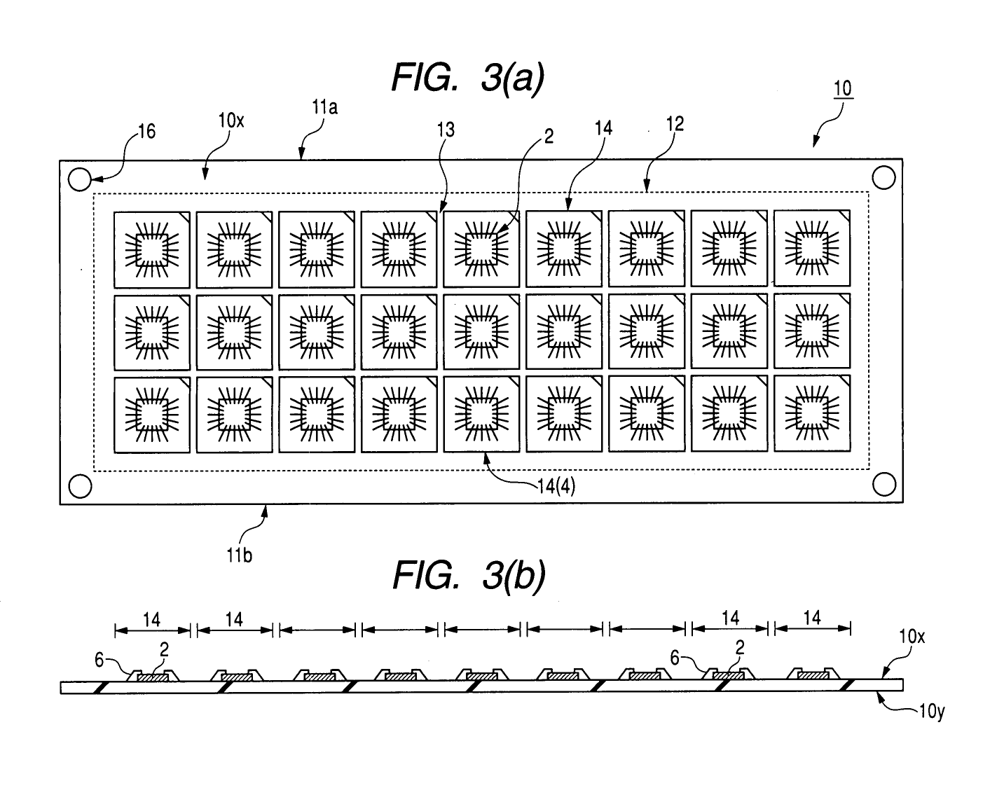

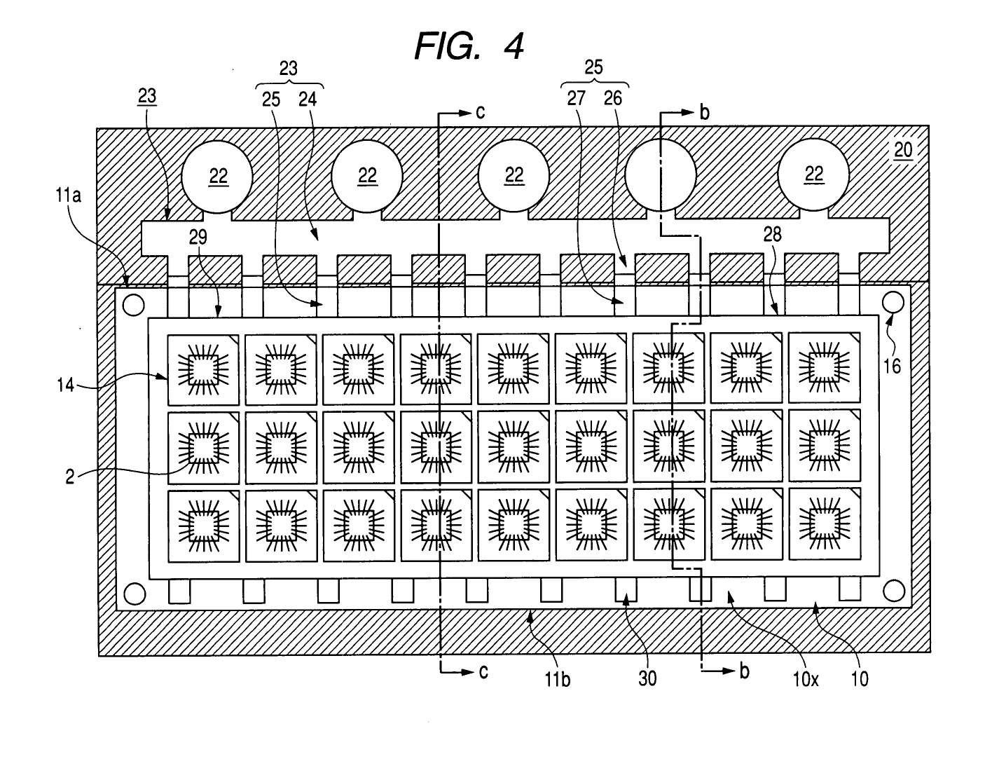

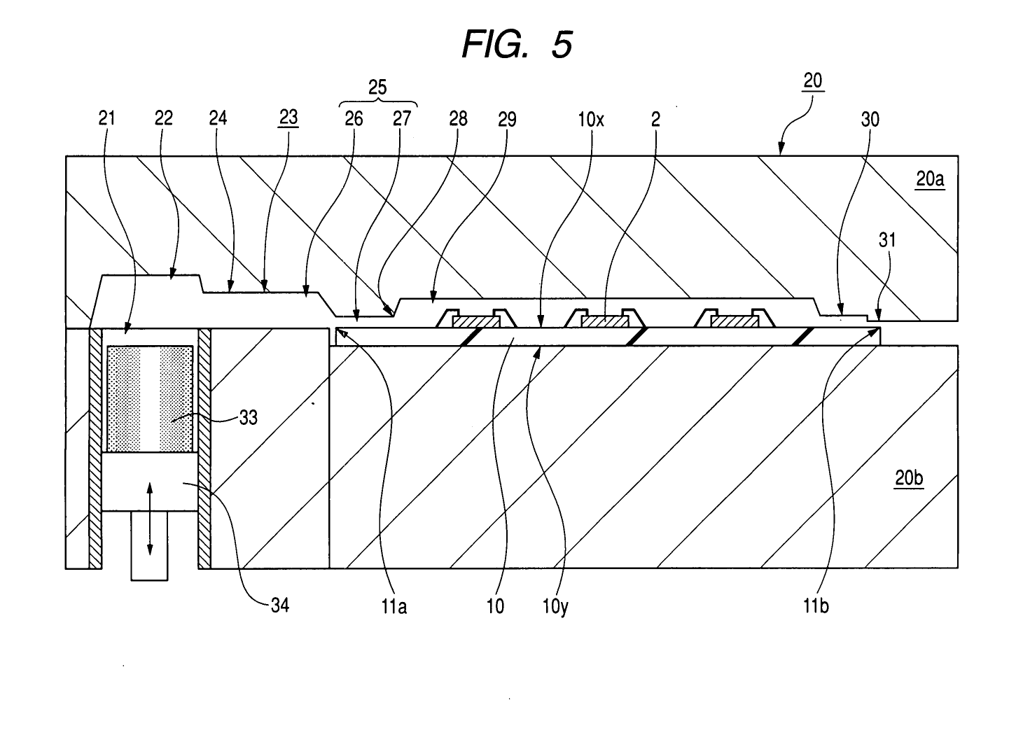

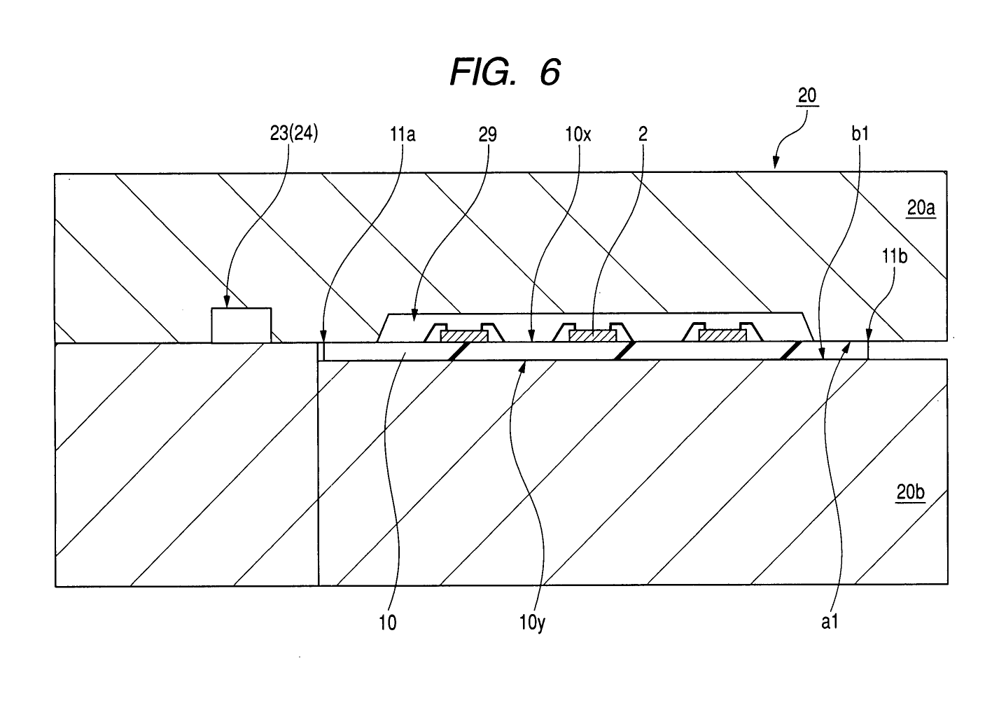

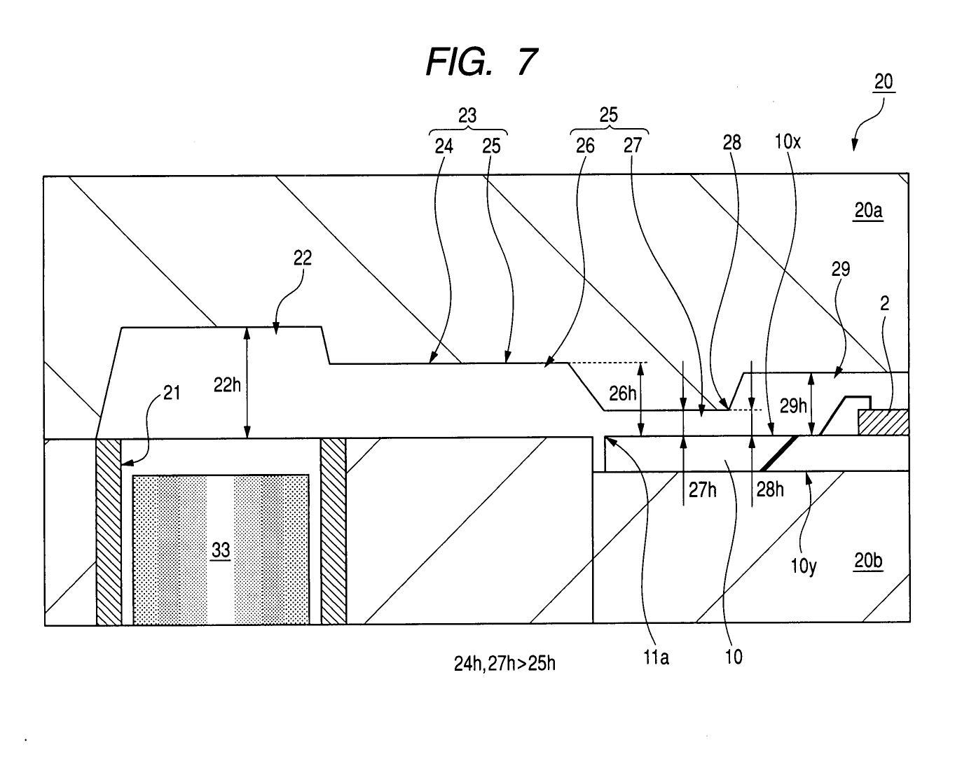

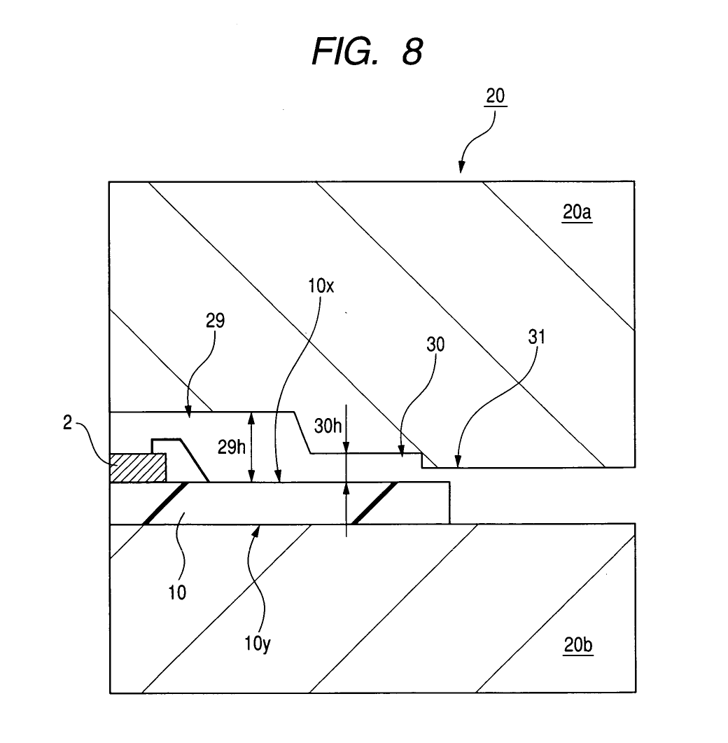

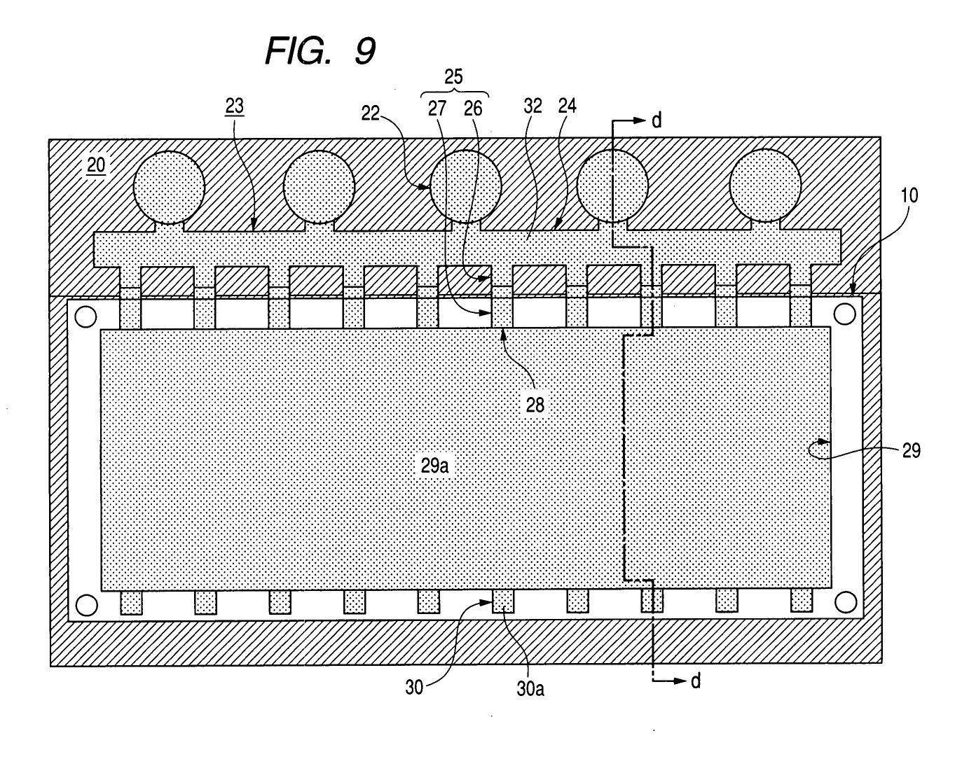

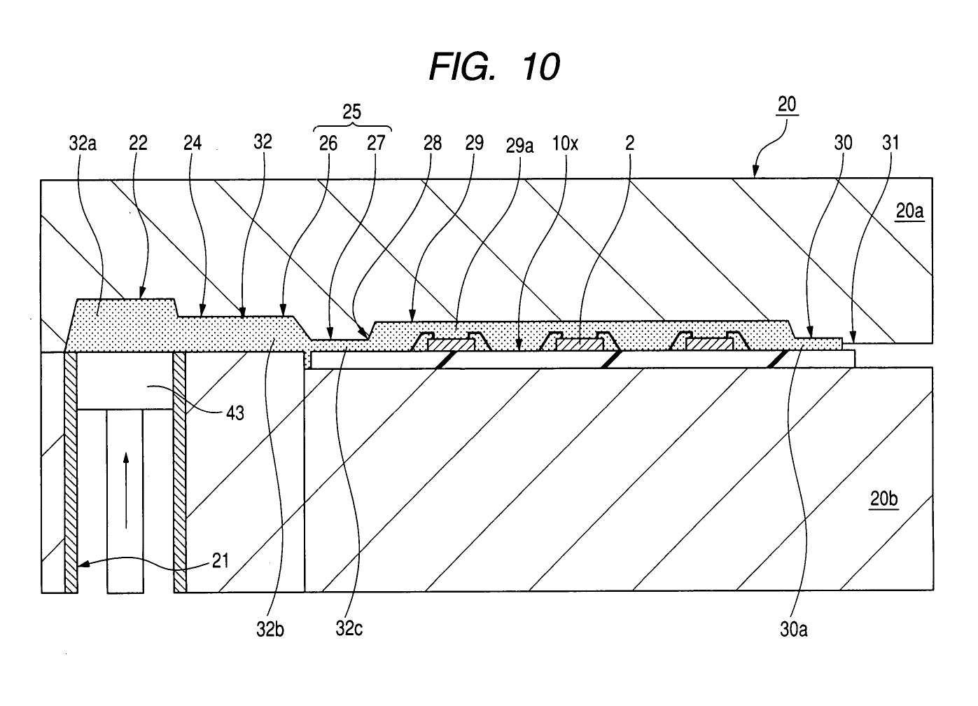

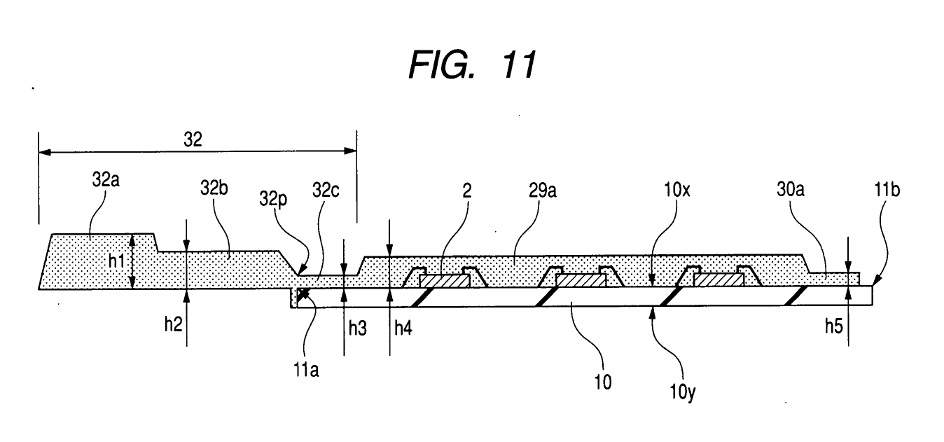

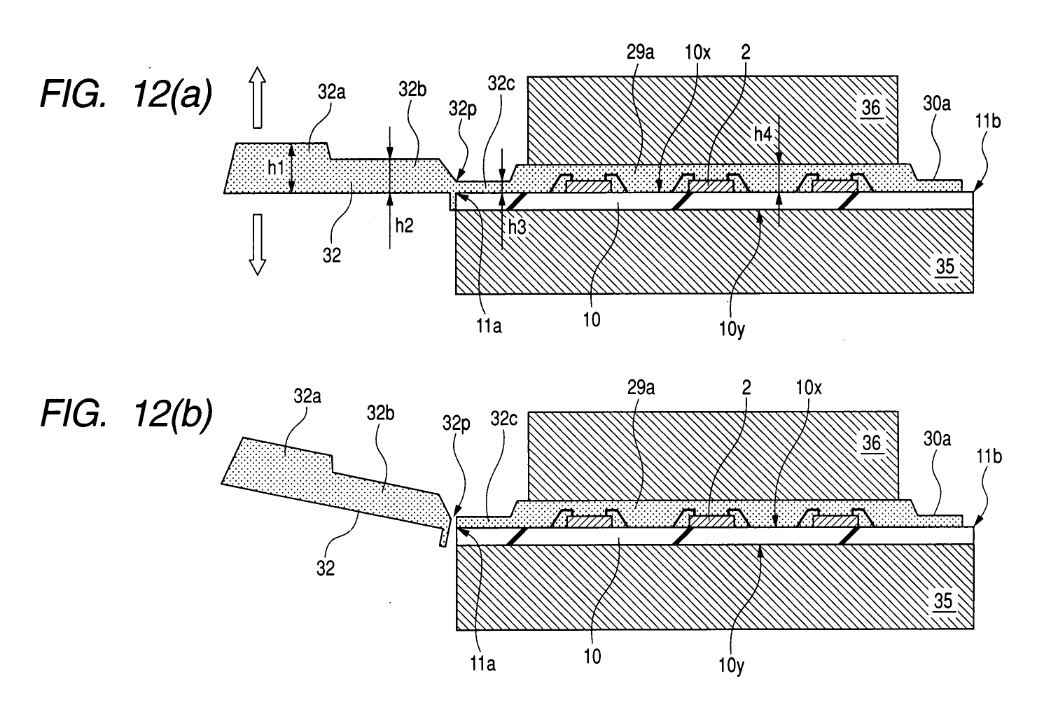

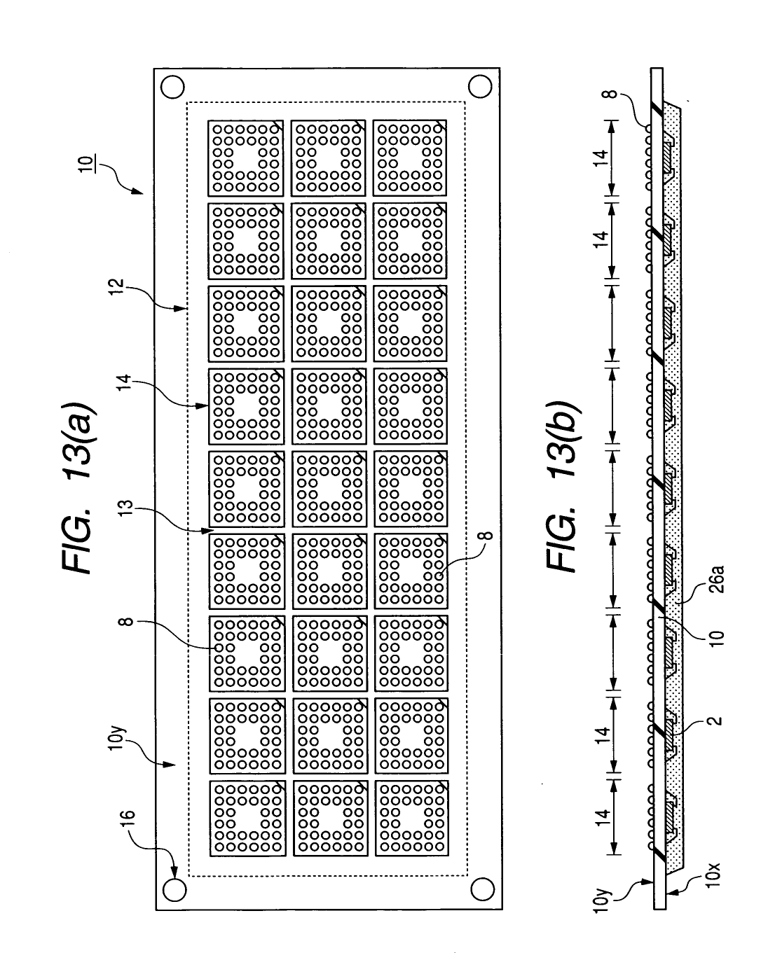

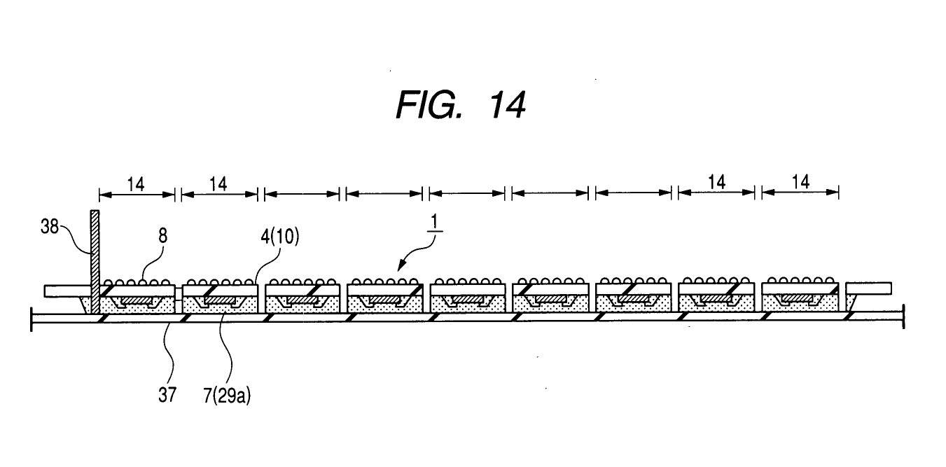

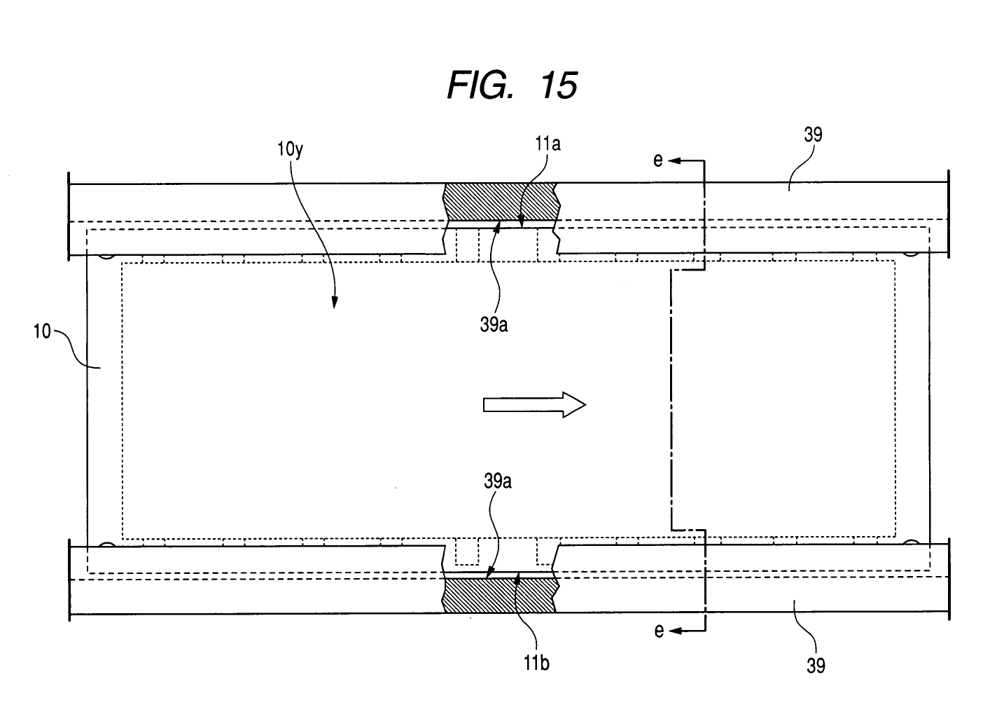

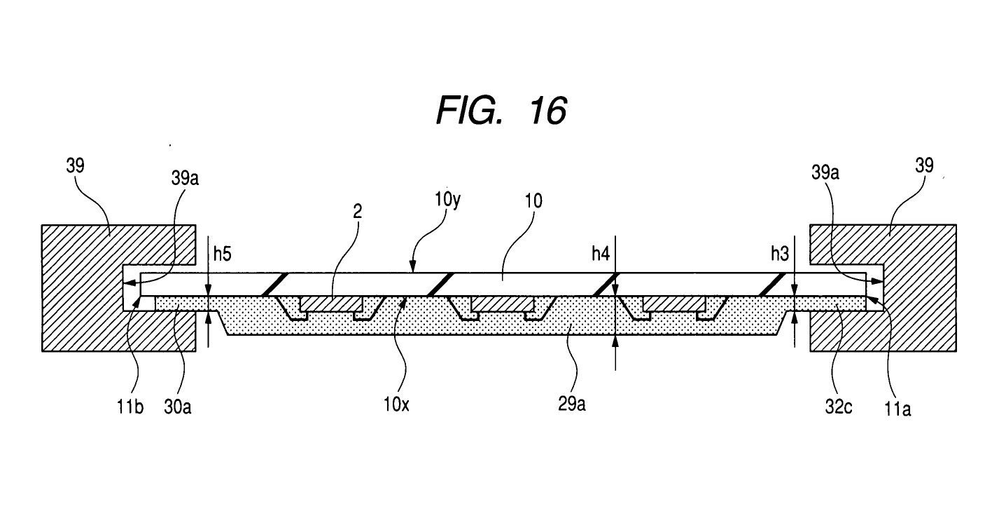

FIGS. 1 to 16 are views relating to a semiconductor device according to the embodiment 1 of the present invention. FIG. 1(a) and FIG. 1(b) are views showing an internal structure of a semiconductor device according to an embodiment 1 of the present invention, in which FIG. 1(a) is a plan view and FIG. 1(b) is a sectional view taken along a line a-a line in FIG. 1(a); FIG. 2(a) and FIG. 2(b) are views showing a configuration of a multi-wiring substrate (multi-chip bonded substrate) used for manufacturing the semiconductor device, in which FIG. 2(a) is a plan view and FIG. 2(b) is a sectional view; FIG. 3(a) and FIG. 3(b) are views showing a state in which semiconductor chips are mounted on the multi-wiring substrate in the manufacture of the semiconductor device, in which FIG. 3(a) is a plan view and FIG. 3(b) is a sectional view; FIG. 4 is a perspective plan view showing a state in which the multi-wiring substrate is clamped by a molding die in the manufacture of the semiconductor device; FIG. 5 is a sectional view taken along a line b-b in FIG. 4: FIG. 6 is a sectional view taken along a line c-c in FIG. 4; FIG. 7 is an enlarged sectional view showing a part (leftward section in the figure) of FIG. 5; FIG. 8 is an enlarged sectional view showing a part (rightward section in the figure) of FIG. 5; FIG. 9 is a perspective plan view showing a state in which resin is injected into a cavity of the molding die to form a resin sealing member in the manufacture of the semiconductor device; FIG. 10 is a sectional view taken along a line d-d in FIG. 9; FIG. 11 is a sectional view showing a state in which the multi-wiring substrate is removed from the molding die after the completion of the resin sealing process in the manufacture of the semiconductor device; FIG. 12(a) and FIG. 12(b) are sectional views for explaining a breaking process in the manufacture of the semiconductor device; FIG. 13(a) and FIG. 13(b) are views for explaining a bump-mounting process in the manufacture of the semiconductor device, in which FIG. 13(a) is a plan view and FIG. 13(b) is a sectional view; FIG. 14 is a sectional view for explaining a dicing process in the manufacture of the semiconductor device; FIG. 15 is a plan view showing a transporting state of the multi-wiring substrate in the manufacture of the semiconductor device; and FIG. 16 is a sectional view taken along a line e-e in FIG. 15.

As shown in FIGS. 1(a) and 1(b), a semiconductor device 1 according to the embodiment 1 has a package structure in which a semiconductor chip 2 is mounted on a main surface 4x of a wiring substrate 4 called interposer and plural ball-shaped soldering bumps 8, for example, are arranged as a projecting electrode on the back surface 4y that is opposite to the main surface 4x of the wiring substrate 4.

A planar shape of the semiconductor chip 2 intersecting its thickness direction is quadrangular, e.g., square in this embodiment. For example, the semiconductor chip 2 comprises a semiconductor substrate, plural transistor elements formed on a main surface of the semiconductor substrate, a thin-film multi-layered laminate formed on the main surface of the semiconductor substrate and a surface protective film formed so as to cover the thin-film multi-layered laminate, although no limitation is made to this construction. The thin-film multi-layered laminate has a structure in which insulating layers and wiring layers are alternately laminated plural times. The semiconductor substrate is made of, for example, single crystal silicon. The insulating layer of the thin-film multi-layered laminate is made of, for example, silicon oxide film or the like. The wiring layer of the thin-film multi-layered laminate is made of, for example, a metal film such as aluminum (Al), aluminum alloy, copper (Cu), copper alloy, or the like. The surface protective film is made of, for example, a multi-layer laminate film consisting of an inorganic insulating film such as silicon oxide film or silicon nitride film and an organic insulating film.

The semiconductor chip 2 has a main surface (circuit formation surface, device formation surface) and a rear surface that are located on opposite sides, and an integrated circuit is formed over the main surface of the semiconductor chip 2. This integrated circuit is mainly composed of transistor elements formed on the main surface of the semiconductor substrate and wirings formed on the thin-film multi-layered laminate.

Plural connecting pads 3 (bonding pads), for example, are arranged as a connecting section on the main surface of the semiconductor chip 2. The plural connecting pads 3 are arranged along each side of the semiconductor chip 2. The plural connecting pads 3 are formed on the uppermost wiring layer out of the thin-film multi-layered laminate and exposed from bonding openings formed in the surface protective film.

A planar shape of the wiring substrate 4 intersecting its thickness direction is quadrangular, e.g., square in this embodiment. The wiring substrate 4 is mainly composed of a core material, a first protective film formed to cover the main surface of the core material and a second protective film formed to cover the rear surface that is opposite to the main surface of the core material, though it is not limited to this structure. The core material has wiring layers (conductive layers) in the main surface and rear surface. The core material is formed of a highly elastic resin substrate made from glass fibers impregnated with an epoxy-based or polyimide-based resin. Each wiring layer of the core material is formed of a metal film essentially composed of Cu, for example. The first and second protective films on the core material are formed to protect mainly wirings formed in the front and rear surfaces of the core material. As the first and second protective films are used an insulating film made from an insulative resin film (solder resist film).

A chip mounting region (device mounting region) is arranged on the main surface 4x of the wiring substrate 4. The back surface of the semiconductor chip 2 is fixedly bonded to this chip mounting region via an adhesive. Plural connecting pads 5 as a connecting section, for example, are arranged on the main surface 4x of the wiring substrate 4. In this embodiment 1, plural connecting pads 5 are arranged around the semiconductor chip 2 (chip mounting region). Plural connecting pads (connecting lands) as a connecting section are arranged on the back surface 4y of the wiring substrate 4. A soldering bump 8 is fixed to each of the plural connecting pads.

Plural connecting pads 3 of the semiconductor chip 2 are electrically connected to the plural connecting pads 5 of the wiring substrate 4 respectively. In this embodiment 1, the electrical connection between the connecting pads 3 of the semiconductor chip 2 and the connecting pads 5 of the wiring substrate 4 is established by bonding wires 6. One end of each of the bonding wires 6 is connected to each of the connecting pads 3 of the semiconductor ship 2, while the other end is connected to each of the connecting pads 5 of the wiring substrate 4.

The bonding wires 6 are gold (Au) wires, for example. The bonding wires 6 are connected by a nail head bonding method making use of ultrasonic vibration for thermal contact bonding.

The semiconductor chip 2 and the plural bonding wires 6 are sealed up with a resin sealing member 7 selectively formed on the main surface 4x of the wiring substrate 4. The resin sealing member 7 is formed from a biphenyl-based thermosetting resin containing a phenolic curing agent, silicone rubber and fillers (such as silica) to reduce stress.

The resin sealing member 7 and the wiring substrate 4 have generally equal plane size, so that the side faces of the resin sealing member 7 are flush with the side surfaces of the wiring substrate 4. As explained in detail later, the semiconductor device 1 according to the embodiment 1 uses a multi-wiring substrate (multi-chip bonded substrate) having plural device forming regions (device regions), wherein a resin sealing member (resin sealing member for collective sealing) used for sealing plural semiconductor chips, that are mounted so as to correspond to each device forming region of the multi-wiring substrate, together at a time is formed, and then, the multi-wiring substrate and resin sealing member for collective sealing are divided into plural pieces, thereby forming the semiconductor device 1.

Subsequently, the multi-wiring substrate used for the manufacture of the semiconductor device 1 will be explained with reference to FIGS. 2(a) and 2(b).

As shown in FIGS. 2(a) and 2(b), a planar shape of the multi-wiring substrate 10 intersecting its thickness direction is quadrangular, e.g., rectangular in this embodiment. A molding area (resin sealing region) 12 is formed in the main surface (chip mounting surface) 10x of the multi-wiring substrate 10, a plurality of device forming regions (device regions) 14 are formed in this molding region 12, and a chip mounting region 15 is formed in each of the device forming regions 14. The chip mounting region 15 is arranged on the main surface 10x of the multi-wiring substrate 10. In the manufacture of the semiconductor device 1, the semiconductor chip 2 is mounted in each chip mounting area 15, and the resin sealing member for sealing up the plural semiconductor chips 2 mounted so as to correspond to the respective device forming regions 14 together at a time is formed in the molding region 12.

Each of the device forming regions 14 is divided by separating regions 13. Each of the device forming regions 14 has basically the same structure and planar shape as those of the wiring substrate 4 shown in FIG. 1. The wiring substrate 4 is formed by dicing each of the plural device forming regions 14 of the multi-wiring substrate 10. In this embodiment 1, the multi-wiring substrate 10 has, for example, twenty-seven device forming regions 14, that is, nine in the X-direction and three in the Y-direction in a matrix (9×3), for example, although the arrangement is not limited thereto.

Positioning holes 16 are formed at each corner of the multi-wiring substrate 10. A pilot pin is inserted into each positioning hole for positioning the multi-wiring substrate 10 to a molding die.

Subsequently, the configuration of the molding die used for the molding process (resin sealing) during the manufacture of the semiconductor device 1 will be explained with reference to FIGS. 4 to 8. The configuration of the molding die will be explained in a state in which the multi-wiring substrate is positioned and clamped between the upper die and the lower die of the molding die.

As shown in FIGS. 4 to 6, the molding die 20 has the upper die 20a and lower die 20b that are overlapped in the vertical direction (Z-direction), pot 21, cull 22, runner (resin flowing path) 23, resin injection gate 28, sealing cavity (resin sealing member forming section) 29, runner (resin flowing path) 30, and air vent section 31. The wiring substrate 10 is arranged between the holding surface (mating face) a1 of the upper die 20a and the holding surface b1 of the lower die 20b as shown in FIG. 6, whereby it is fixedly held by clamping force exerted when the upper die 20a and the lower die 20b are clamped.

As shown in FIG. 5, the cull 22, runner 23, resin injection gate 28, sealing cavity 29, runner 30, and air vent section 31 are formed at the upper die 20a, wherein these are made of recess sections dented in the depth direction from the holding face a1 of the upper die 20a, although the structure is not limited thereto. The pot 21 is provided at the lower die 20b, for example, although the structure is not limited thereto.

As shown in FIGS. 4 and 5, the sealing cavity 29 is positioned on the main surface 10x of the multi-wiring substrate 10 so as to cover the semiconductor chips 2 mounted on the multi-wiring substrate 10. The sealing cavity 29 has a size (planar size) that can collectively cover the plural device forming regions 14 of the multi-wiring substrate 10. The planar shape of the sealing cavity 29 is a rectangular corresponding to the planar shape of the multi-wiring substrate 10.

Plural culls 22 are formed (five in this embodiment 1) Each of the plural culls 22 is positioned at the outside of one long side 11a (one long side of two opposite long sides of the sealing cavity 29) of two opposite long sides (11a, 11b) of the multi-wiring substrate 10.

The runner 23 is mainly composed of a main runner 24 extending along one long side 11a of the multi-wiring substrate 10 and plural sub-runners 25 (ten in this embodiment 1), although the structure is not limited thereto. The main runner 24 is positioned between the plural culls 22 and the sealing cavity 29, and communicates with each of the plural culls 22. The plural sub-runners 25 are positioned between the main runner 24 and the sealing cavity 29, and arranged along one long side 11a (one long side of the sealing cavity 29) of the multi-wiring substrate 10. The plural sub-runners 25 have one end communicating with the main runner 24 and the other end communicating with the sealing cavity 29.

The resin injection gate 28 is provided at the joint section of the sub-runner 25 and the sealing cavity 29. The number of the resin injection gate 28 is equal to the number of the sub-runners 25.

Plural runners 30 are provided (the number of the runners is equal to the number of the sub-runners 25 in this embodiment 1). The plural runners 30 are positioned along the other long side 11b (the other long side of the sealing cavity 29) of the multi-wiring substrate 10. One end of each of the plural runners 30 communicates with the sealing cavity 29.

The air vent section 31 is provided so as to communicate with the other end of the runner 30. The number of the air vents is equal to the number of the runners 30.

Plural pots 21 are provided so as to correspond to the culls 22. The plural pots 21 are arranged at the position overlapping with the culls 22.

As shown in FIGS. 4 and 5, the plural sub-runners 25 cross one side 11a (periphery) of the multi-wiring substrate 10 from the outside of the multi-wiring substrate 10 to communicate with the sealing cavity 29. Each of the plural sub-runners 25 has a first portion 26 positioned at the outside of the multi-wiring substrate 10 and a second portion 27 communicating with the first portion 26 and the sealing cavity 29 and positioned on the main surface 10x of the multi-wiring substrate 10. As shown in FIG. 7, the height 27h of the second portion 27 from the main surface 10x of the multi-wiring substrate 10 is lower than the height 26h of the first portion 26 from the main surface 10x of the multi-wiring substrate 10, and further, lower than the height 29h of the sealing cavity 29 from the main surface 10x of the multi-wiring substrate 10. In this embodiment 1, the height 26h of the first portion 26 of the sub-runner 25 is, for example, made equal to the height of the main runner 24 from the main surface 10x of the multi-wiring substrate 10. The height 27h of the second portion 27 of the sub-runner 25 is made equal to the height 28h of the resin injection gate 28 from the main surface 10x of the multi-wiring substrate 10.

The first portion 26 and the second portion 27 of each of the plural sub-runners 25 extend along the direction crossing one long side 11a of the multi-wiring substrate 10. The second portion 27 terminates at one long side 11a of the multi-wiring substrate 10.

The height 30h of each of the plural runners 30 from the main surface 10x of the multi-wiring substrate 10 is lower than the height 29h of the sealing cavity 29 as shown in FIG. 8. In this embodiment 1, the height 30h of the runner 30 is made equal to the height 27h of the second portion 27 of the sub-runner 25, for example.

Subsequently, the manufacture of the semiconductor device 1 will be explained with reference to FIGS. 2 to 16.

Firstly, the multi-wiring substrate 10 shown in FIG. 2 and the molding die 20 shown in FIGS. 4 to 6 are prepared.

Then, as shown in FIGS. 3(a) and 3(b), semiconductor chips 2 are fixedly bonded to the respective chip mounting regions 15 in the plural device forming regions 14 of the multi-wiring substrate 10 via an adhesive. The semiconductor chips 2 are fixedly bonded such that the back surfaces of the semiconductor chips 2 face the main surface 10x of the multi-wiring substrate 10.

Subsequently at the device forming regions 14 of the multi-wiring substrate 10, as shown in FIGS. 3(a) and 3(b), the plural connecting pads 5 (see FIG. 1(a)) of the device forming regions 14 and the plural connecting pads 3 (see FIG. 1(a)) of the semiconductor chips 2 mounted on the device forming regions 14 are electrically connected with plural bonding wires 6. By this process, plural semiconductor chips 2 are mounted over the main surface 10x of the multi-wiring substrate 10 so as to correspond to the plural device forming regions 14.

Here, the mounting means the state in which the semiconductor chips are fixedly bonded to the substrate and the connecting pads of the multi-wiring substrate and the connecting pads of the semiconductor chips are electrically connected. In this embodiment 1, the semiconductor chips 2 are fixedly bonded by the adhesive, and the electrical connection between the connecting pads (5) of the multi-wiring substrate 10 and the connecting pads (3) of the semiconductor chips 2 are established by bonding wires 6.

Then, as shown in FIGS. 4 to 6, the multi-wiring substrate 10 is positioned and clamped between the upper die 20a and the lower die 20b of the molding die 20. In this case, the multi-wiring substrate 10 is positioned by inserting pilot pins of the molding die 20 into the positioning holes 16 of the multi-wiring substrate 10. The multi-wiring substrate 10 is fixedly held by clamping force caused when the upper die 20a and the lower die 20b are clamped. The pot 21, cull 22, runner 23, resin injection gate 28 and sealing cavity 29 of the molding die 20 have the structure described above.

Before the upper die 20a and the lower die 20b are clamped, resin tablet 33 heated in advance is put into each pot 21. The resin tablet 33 is formed from a biphenyl-based thermosetting resin containing a phenolic curing agent, silicone rubber and fillers (such as silica).

Subsequently, the molding die 20 is heated to melt the resin tablet 33 for raising the plunger 34 in the pot 21. As shown in FIGS. 9 and 10, the melted thermosetting resin is injected into the sealing cavity 29 through the pot 21, cull 22, runner 23, and resin injection gate 28 by the pressure due to the rise of the plunger 34. The plural semiconductor chips 2 mounted on the main surface 10x of the multi-wiring substrate 10 so as to correspond to each of the plural device forming regions 14 of the multi-wiring substrate 10 are sealed with the thermosetting resin injected into the sealing cavity 29. The resin sealing member 29a is formed in the sealing cavity 29 by curing the thermosetting resin that seals the semiconductor chips 2.

Since the thermosetting resin is injected into the sealing cavity 29 through the pot 21, cull 22, runner 23, and resin injection gate 28 of the molding die 20 during this resin sealing process, a resin member (unnecessary resin member) 32 is formed, as shown in FIGS. 9 and 10, from the thermosetting resin remaining on the cull 22, runner 23, or the like, separate from the resin sealing member 29a formed at the sealing cavity 29. This resin member 32 is integrally formed with the resin sealing member 29a.

Further, the thermosetting resin is injected into the runner 30 that is opposite to the runner 23 during this process, so that a resin member (unnecessary resin member) 30a integrated with the resin sealing member 29a is formed from the thermosetting resin injected into the runner 30.

Then, a curing process is performed for stabilizing the cure of the resin sealing member 29a, and then, the molding die is opened to remove the multi-wiring substrate 10 from the molding die 20 as shown in FIG. 11.

The resin members 32 and 30a will be explained with reference to FIG. 11.

Since the resin member 32 is formed from the thermosetting resin remaining on the cull 22, runner 23, or the like of the molding die 20, it is made into the shape generally same as that of the cull 22 or runner 23. Therefore, the resin member 32 is integrally formed with the resin sealing member 29a so as to cross one long side 11a of the multi-wiring substrate 10 from the outside of the long side 11a.

The resin member 32 is composed of a first resin portion 32a corresponding to the cull 21 of the molding die 20, a second resin portion 32b corresponding to the main runner 24 and the first portion 26 of the sub-runner 25 of the molding die 20, and a third resin portion 32c corresponding to the second portion 27 of the sub-runner 25 of the molding die 20. The first and second resin portions (32a, 32b) are positioned at the outside of the multi-wiring substrate 10, wherein the second resin portion 32b communicates with the first resin portion 32a. The third resin portion 32c is positioned on the main surface 10x of the multi-wiring substrate 10 and communicates with the second resin portion 32b and the resin sealing member 29a.

The thickness (height) h3 of the third resin portion 32c from the main surface 10x of the multi-wiring substrate 10 is thinner (lower) than the thickness (height) h2 of the second resin portion 32b from the main surface 10x of the multi-wiring substrate 10, and further, thinner (lower) than the thickness (height) h4 of the resin sealing member 29a from the main surface 10x of the multi-wiring substrate 10. The thickness (height) h1 of the first resin portion 32a from the main surface 10x of the multi-wiring substrate 10 is thicker than the thickness h2 of the second resin portion 32b.

The second and third resin portions (32b, 32c) of the resin member 32 extend along the direction crossing one long side 11a of the multi-wiring substrate 10, and the third resin portion 32c terminates at one long side 11a of the multi-wiring substrate 10.

In the resin member 32 thus configured, the thickness of the third resin portion 32c adhered to the main surface 10x of the multi-wiring substrate 10 is thinner than the thickness of the first and second resin portions (32a, 32b) positioned at the outside of the multi-wiring substrate 10, and further, the third resin portion 32c terminates at one long side 11a of the multi-wiring substrate 10. Therefore, when the resin member 32 is bent in the thickness direction of the multi-wiring substrate 10 with respect to the resin sealing member 29a, bending stress is concentrated on the joint section (separation section 32p) between the second resin portion 32b and the third resin portion 32c, with the result that a crack can be produced on the separation section 32p.

Since the resin member 30a is formed from the thermosetting resin remaining on the runner 30 of the molding die 20, it is made into the shape generally the same as that of the runner 30. Accordingly, the resin member 30a is formed on the main surface 10x of the multi-wiring substrate 10 at the other long side 11b thereof. Further, the resin member 30a has one end communicating with the resin sealing member 29a and the other end terminating at the inside of the other long side 11b of the multi-wiring substrate 10. The thickness (height) h5 of the resin member 30a from the main surface lox of the multi-wiring substrate 10 is thinner than the thickness h4 of the resin sealing member 29a. In this embodiment 1, the thickness h5 of the resin member 30a is set equal to the thickness h3 of the third resin portion 32c of the resin member 32, for example.

Subsequently, as shown in FIG. 12(a), the multi-wiring substrate 10 arranged on the stage 35 is fixed by the package holding member 36, and then, the resin member 32 is bent in the thickness direction of the multi-wiring substrate 10 with respect to the resin sealing member 29a such that bending stress is concentrated on the separation section 32p of the resin member 32, thereby producing a crack on the separation section 32p. Thus, as shown in FIG. 12(b), the resin member 32 is separated at the separation section 32p, whereby the first and second resin portions (32a, 32b) of the resin member 32 positioned at the outside of the multi-wiring substrate 10 are removed.

Then, as shown in FIGS. 13(a) and 13(b), plural soldering bumps 8 are mounted so as to correspond to each of the device forming regions 14 at the back surface 10y, that is opposite to the main surface 10x, of the multi-wiring substrate 10. The soldering bump is mounted such that a flux is applied on the connecting pad on the back surface 10y of the multi-wiring substrate 10, a soldering ball is supplied on the connecting pad, and then, the soldering ball is melted to be bonded to the connecting pad, although the structure is not limited thereto.

Subsequently, the flux used in the soldering bump mounting process is removed by washing, and then, an identification mark such as a name of a product, manufacturer's name, type of a product, manufacture lot number, or the like is formed on the upper face of the resin sealing member 29a so as to correspond to each of the device forming regions 14 of the multi-wiring substrate 10 by an ink jet marking method, direct printing method, laser marking method, or the like.

Then, as shown in FIG. 14, the multi-wiring substrate 10 and the resin sealing member 29a are divided into plural pieces corresponding to each device forming region 14. This division is performed such that, as shown in FIG. 14, the multi-wiring substrate 10 and the resin sealing member 29a are diced with a dicing blade 38 along the separation section 13 of the multi-wiring substrate 10 with the resin sealing member 29a attached to a dicing sheet 37. According to this process, the semiconductor device 1 shown in FIG. 1 is almost completed.

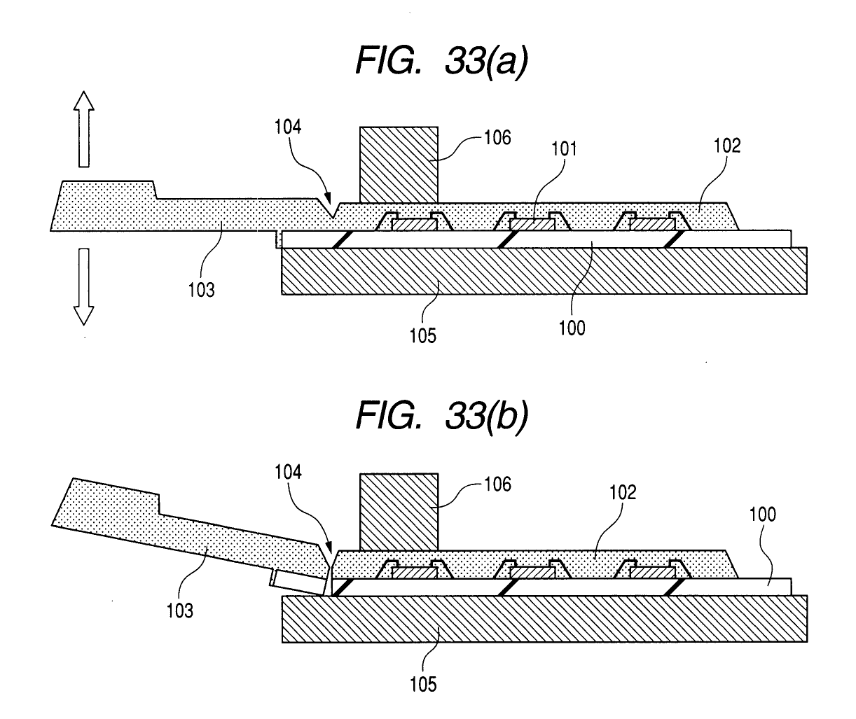

In the conventional gate breaking process, as shown in FIG. 33(a), the resin member 103 is bent in the thickness direction of the multi-wiring substrate 100 with respect to the resin sealing member 102 for separating the resin member 103 from the resin sealing member 102 at the separation section 104 corresponding to the resin injection gate of the molding die. Specifically, the resin member 103 is separated from the resin sealing member 102 at the inside of the periphery of the multi-wiring substrate 100. Therefore, bending stress is also exerted on the multi-wiring substrate 100 by the influence due to the adherence between the resin member 103 and the multi-wiring substrate 100. As a result, deficiency is likely to occur with the reduced size of the substrate, such as breakdown of the multi-wiring substrate 100, as shown in FIG. 33(b).

On the other hand, in the resin member 32 in the embodiment 1, the thickness of the third resin portion 32c positioned on the main surface of the multi-wiring substrate 10 is thinner than the thickness of the second resin portion 32b, and the third resin portion 32c terminates at the periphery (one long side 11a) of the multi-wiring substrate 10, as shown in FIG. 12. Therefore, when the resin member 32 is bent in the thickness direction of the multi-wiring substrate 10 with respect to the resin sealing member 29a, bending stress is concentrated on the joint section (separation section 32p) between the second resin portion 32b and the third resin portion 32c of the resin member 32, whereby a crack is produced on the resin member 32 at the periphery of the multi-wiring substrate 10. Specifically, when the resin member 32 is bent in the thickness direction of the multi-wiring substrate 10 with respect to the resin sealing member 29a, bending stress exerted on the multi-wiring substrate 10 can be reduced. Therefore, even if the rigidity of the multi-wiring substrate 10 is decreased with the reduced size of the multi-wiring substrate, the breakdown of the multi-wiring substrate 10 can be prevented. As a result, production yield of the semiconductor device 1 can be enhanced.

The third resin portion 32c of the resin member 32 desirably terminates at one long side 11a (periphery) of the multi-wiring substrate 10 as disclosed in the embodiment 1, but the third resin portion 32 may terminate at the position on the main surface 10x of the multi-wiring substrate 10 and in the vicinity of one long side 11a of the multi-wiring substrate 10, i.e., at the position slightly inward of one long side 11a of the multi-wiring substrate 10.

As the termination of the third resin portion 32c approaches the resin sealing member 29a, the thick third resin portion 32b goes into the inner side of one long side 11a of the multi-wiring substrate 10, so that bending stress is easy to be exerted on the multi-wiring substrate 10. Accordingly, the termination of the third resin portion 32c is desirably made close to the long side 11a of the multi-wiring substrate 10 as much as possible.

In case where the third resin portion 32c terminates at the outside of the long side 11a of the multi-wiring substrate 10, the resin member 32 is separated at the outside of the periphery of the multi-wiring substrate 10. Further, the position from which the resin member 32 is separated varies. These problems affect the transportation or handling of the multi-wiring substrate 10 after the breaking process. Therefore, the third resin portion 32c desirably terminates at the periphery of the multi-wiring substrate 10 or at the portion slightly inward from the periphery of the multi-wiring substrate 10.

The termination position of the third resin portion 32c can easily be changed by changing the termination of the joint section between the first portion 26 and the second portion 27 of the sub-runner 25, i.e., the termination of the second portion 27 in the molding die 20.

As shown in FIGS. 15 and 16, the multi-wiring substrate 10 that has been subject to the breaking process is transported to the next bump-mounting process along a pair of transporting rails 39 that are spaced from each other. The planar shape of the multi-wiring substrate 10 is generally a rectangle, so that it is transported along the direction of its long side. Specifically, as shown in FIGS. 15 and 16, a groove 39a is formed at each of the pair of transporting rails 39 so as to be opposite to each other. One long side 11a of the multi-wiring substrate 10 is fitted into the groove 39a of one of transporting rails 39, while the other long side 11b is fitted into the groove 39a of the other one of the transporting rails 39. Since soldering bumps 8 are mounted at the back surface 10y of the multi-wiring substrate 10 at the bump-mounting process, the multi-wiring substrate 10 is transported in a state where the back surface 10y that is opposite to the main surface lox having the resin sealing member 29a formed thereon faces upward.

The resin member 32c composed of the third resin portion 32c that is left at the separation of the resin member 32 is formed at one long side 11a of the main surface 10x of the multi-wiring substrate 10. Further, the resin member 30a having the thickness same as that of the resin member 32c is formed at the other long side 11b of the main surface 10x of the multi-wiring substrate 10. Specifically, the multi-wiring substrate 10 has the resin members (32c, 30a), each having the same thickness, formed at the respective long sides of the main surface 10x that is opposite to the back surface 10y on which the soldering bumps 8 are to be mounted. With this configuration, the multi-wiring substrate 10 can be held substantially parallel to the pair of transporting rails 39 as shown in FIG. 16 when the multi-wiring substrate 10 is transported along the pair of transporting rails 39 with the back surface 10y facing upward, whereby the stability upon the transportation of the substrate can be enhanced, and hence, the poor transportation of the substrate can be prevented. As a result, productivity of the semiconductor device 1 can be enhanced.

In the mold array package, the ratio of the plane area to the height of the cavity is extremely great. Therefore, the thermosetting resin should be rapidly and uniformly injected during a limited time from when the curing of the thermosetting resin is started to when its fluidity is reduced. In view of this, thermosetting resin having low viscosity and high fluidity should be used in the mold array package.

The melted thermosetting resin contains plural bubbles. These bubbles in the resin are removed when the resin flows into the cull 22 and the runner 23. However, the thermosetting resin having high fluidity rapidly flows in the cull 22 and the runner 23, so that it is difficult to remove bubbles.

In view of this, the thickness of the second portion 27 is lower than that of the first portion 26 in the sub-runner 25 in this embodiment 1. The flow resistance of the resin increases at this second portion 27. Therefore, even if the thermosetting resin having low viscosity and high fluidity is used, bubbles can be removed during the flow of the resin into the cull 22 and the runner 23. Consequently, the occurrence of a void can be prevented, whereby the poor molding of the resin sealing member 29a can be prevented.

As explained above, the following effects can be obtained according to the embodiment 1.

(1) The breakdown of the multi-wiring substrate 10 can be prevented, whereby production yield of the semiconductor device 1 can be enhanced.

(2) The poor transportation of the multi-wiring substrate 10 along the pair of transporting rails 39 with the back surface 10y, that is opposite to the main surface 10x having the resin sealing member 29a formed thereon, facing upward can be prevented, whereby productivity of the semiconductor device 1 can be enhanced.

(3) The occurrence of void can be presented, whereby production yield of the semiconductor device 1 can be enhanced.

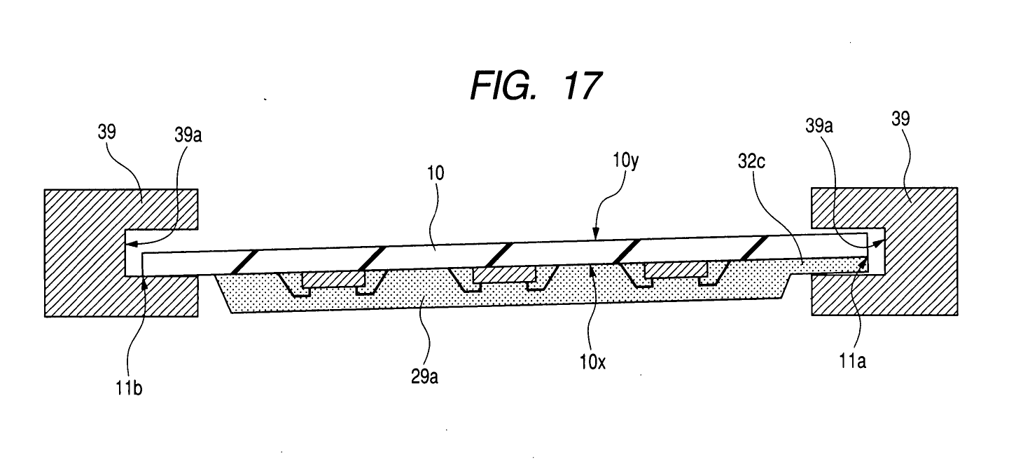

FIG. 17 is a sectional view of a multi-wiring substrate in the manufacture of the semiconductor device according to a modified example 1 of the embodiment 1.

In the embodiment 1, resin members (32c, 30a) each having the same thickness are formed at the respective long sides of the main surface 10x that is opposite to the back surface 10y on which soldering bumps 8 are to be mounted. However, in this modified example 1, the resin member 30a is not formed at the other long side 11b of the main surface 10x of the multi-wiring substrate 10 as shown in FIG. 17, different from the embodiment 1.

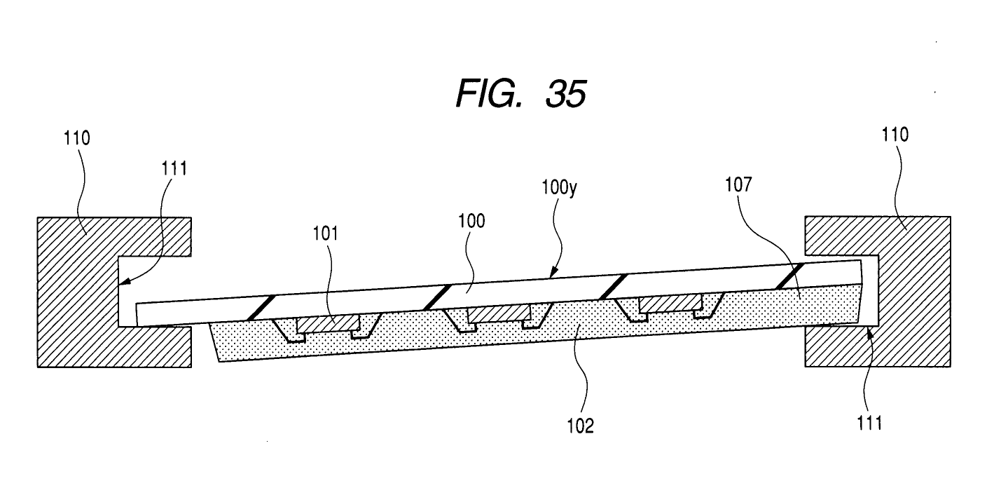

However, since the thickness of the resin member 32c formed at one long side 11a of the main surface 10x of the multi-wiring substrate 10 is thinner than the thickness of the resin sealing member 29a, the angle of inclination (amount of inclination) of the multi-wiring substrate 10 to the pair of transporting rails 39 can be reduced, compared to the conventional case in which the thickness of the projecting resin member 107 is made equal to the thickness of the resin sealing member 101 as shown in FIG. 35. Therefore, the poor transportation can be prevented even if the resin member 32c is formed only at the long side 11a of the main surface of the multi-wiring substrate 10.

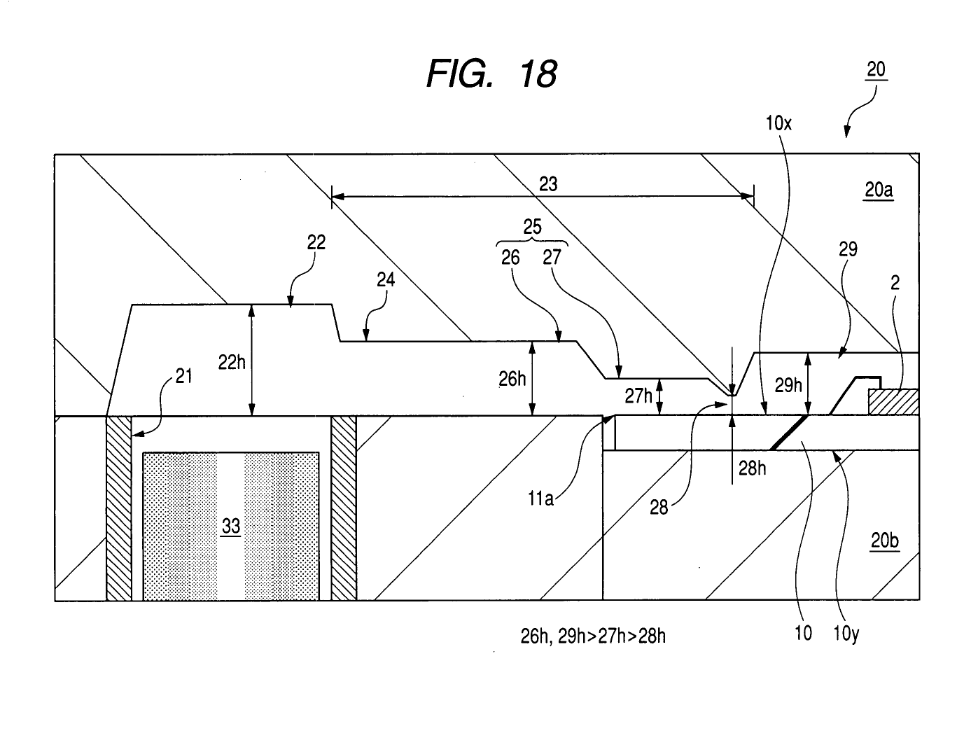

FIG. 18 is a sectional view showing a state in which the multi-wiring substrate is clamped by the molding die during the manufacture of the semiconductor device according to a modified example 2 of the embodiment 1.

In the embodiment 1, the height of the second portion 27 of the sub-runner 25 is set equal to the height 28h of the resin injection gate 28 from the main surface lox of the multi-wiring substrate 10 in the molding die 20. On the other hand, in the modified example 2, the height 27h of the second portion 27 of the sub-runner 25 is higher than the height 28h of the resin injection gate 28 from the main surface 10x of the multi-wiring substrate 10. The effects same as those in the embodiment 1 can be obtained even if the molding die 20 is thus configured.

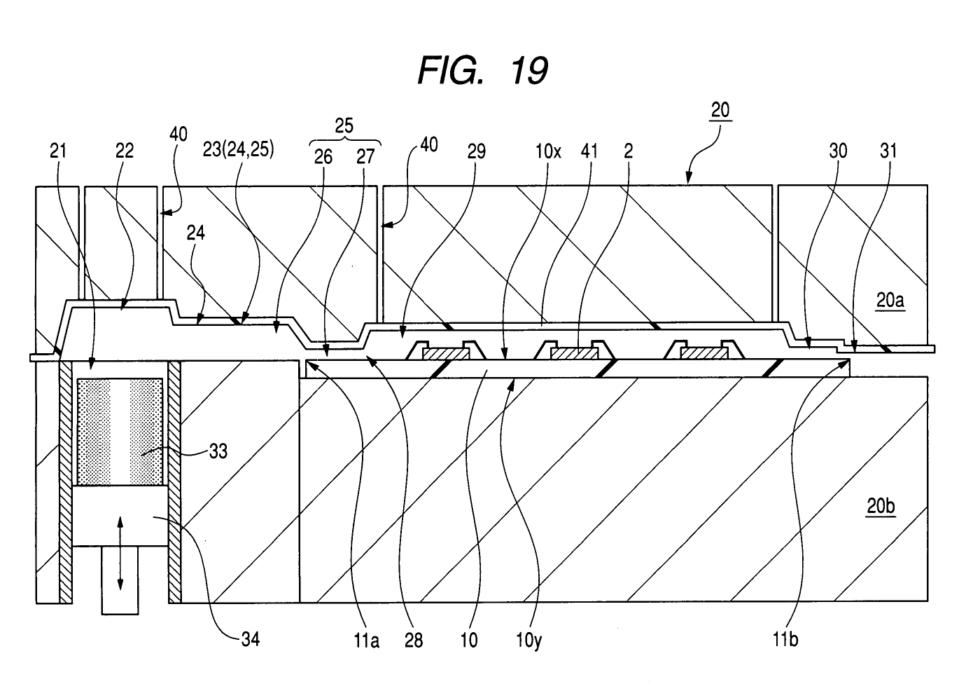

FIG. 19 is a sectional view showing a state in which a multi-wiring substrate is clamped by a molding die during the manufacture of a semiconductor device according to a modified example 3 of the embodiment 1.

In the mold array package, the ratio of the plane area to the height (thickness) of the sealing cavity is extremely great, so that the mold release for releasing the resin sealing member from the cavity becomes difficult. In view of this, a laminate method is used in the mold array package. In the laminate method, a film 41 is adhered onto the inner face of the cull 22, runner 23, sealing cavity 29, resin injection gate 28, and the like of the molding die 20, and the holding surface a1 of the upper die 22a, whereby the resin sealing member 29 is formed by injecting the thermosetting resin into the sealing cavity 29 through the pot 21, cull 22, runner 23 and resin injection gate 28. The film 41 is arranged between the upper die 22a and the lower die 22b so as to cover the whole holding surface a1 of the upper die 22a, and the film 41 is adhered by the suction force from a suction port 40 provided at the upper die 22a. As the film 41, a film having flexibility made of resin is used for example.

In case where the film 41 is adhered as described above, wrinkles are likely to be generated on the film 41 from the sub-runner 25 to the sealing cavity 29, since the width of the sub-runner 25 is extremely narrow compared to that of the sealing cavity 29. Moreover, plural sub-runners 25 form irregularities that make it easy to produce wrinkles.

However, the height 27h of the second portion 27 of the sub-runner 25 positioned on the main surface 10x of the multi-wiring substrate 10 (positioned at the side of the sealing cavity 29) is lower than the height 29h of the sealing cavity 29. Therefore, wrinkles produced on the film 41 from the second portion 27 of the sub-runner 25 to the sealing cavity 29 can be restrained. As a result, poor molding of the resin sealing member 29a caused by the wrinkles on the film 41 can be prevented, whereby production yield of the semiconductor device 1 can be enhanced.

Plural runners 30 communicating with the cavity 29 are also provided at the molding die 20 at the other long side of the cavity 29 (at the other long side 11b of the multi-wiring substrate 10). The film 41 is adhered onto the inner faces of the runner 30. Since the height 30h of each runner 30 is lower than the height 29h of the sealing cavity 29, the wrinkles on the film 41 from the runners 30 to the sealing cavity 29 can also be restrained.

### Embodiment 2

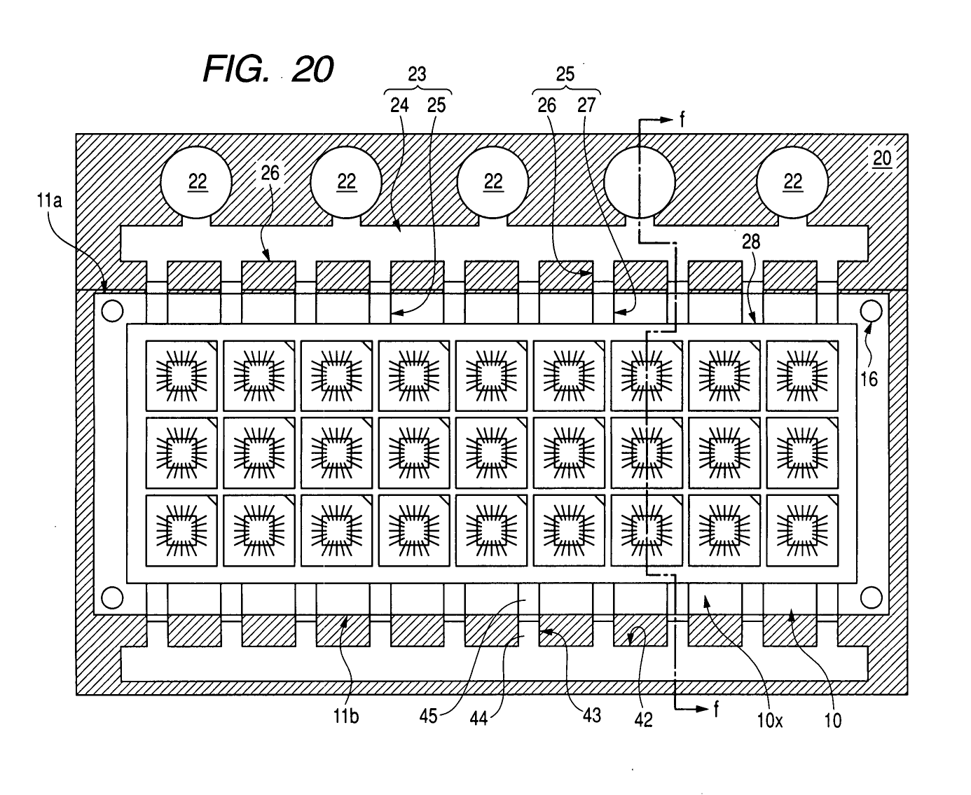

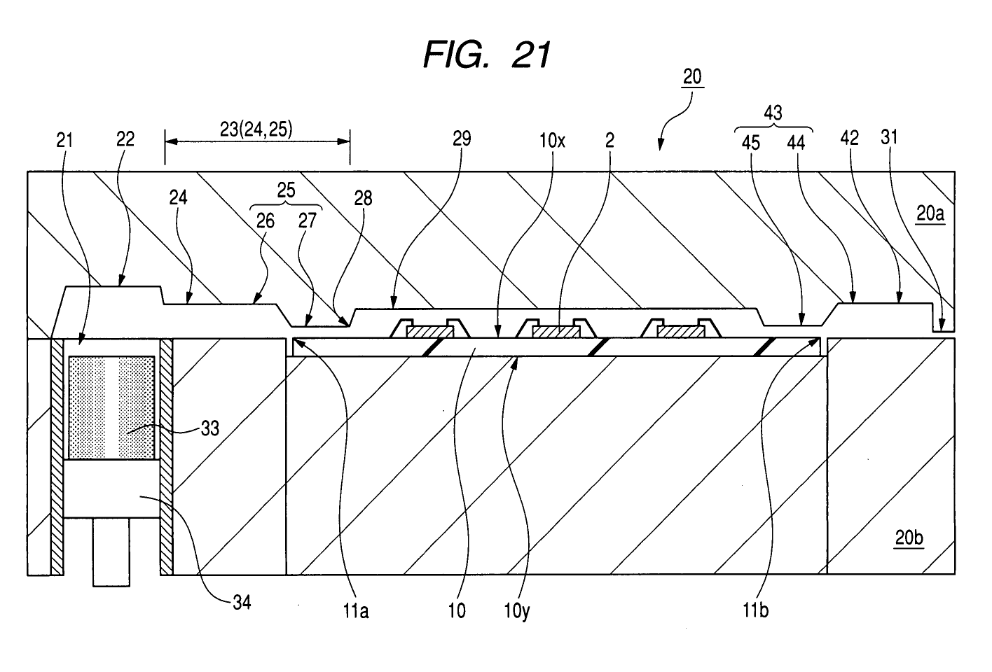

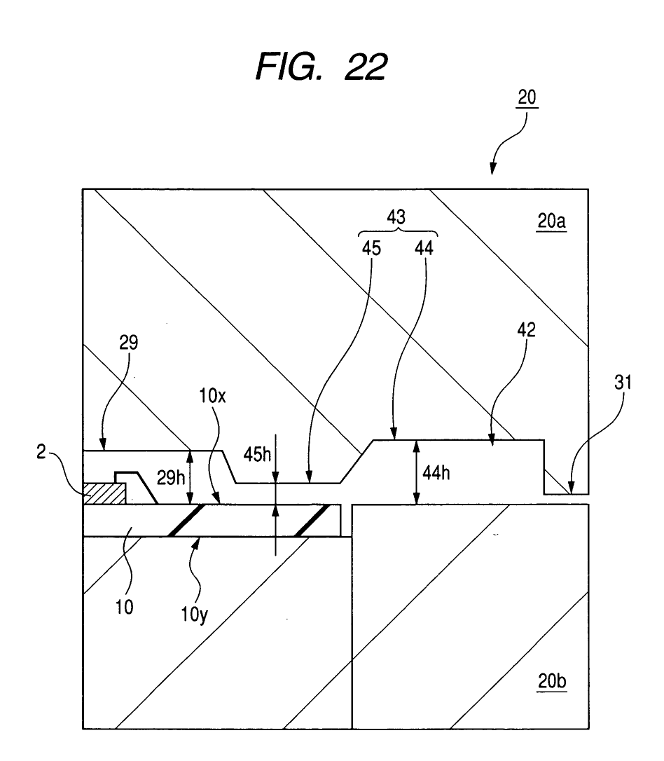

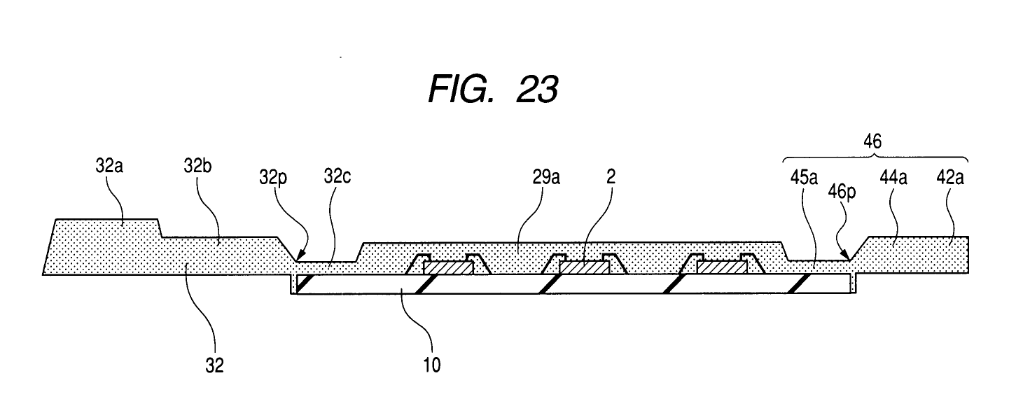

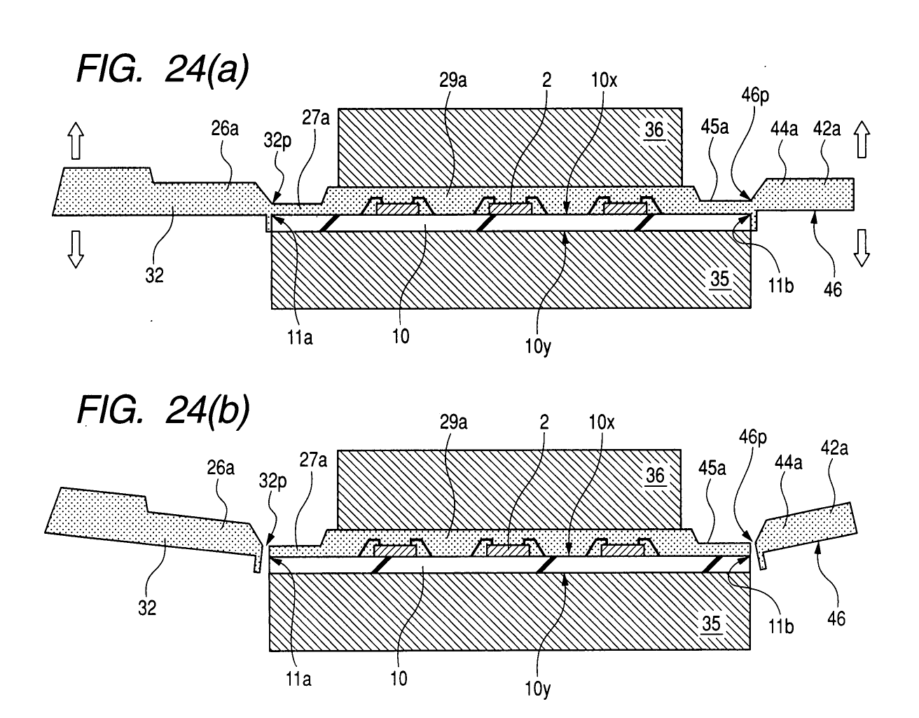

FIGS. 20 to 24 are views relating to a semiconductor device according to the embodiment 2 of the present invention, wherein FIG. 20 is a perspective plan view showing a state in which the multi-wiring substrate is clamped by the molding die in the manufacture of the semiconductor device; FIG. 21 is a sectional view taken along a line f-f in FIG. 20; FIG. 22 is an enlarged sectional view of a part (rightward section in the figure) of FIG. 21; FIG. 23 is a sectional view showing a state in which the multi-wiring substrate is removed from the molding die after the completion of the resin sealing process in the manufacture of the semiconductor device; and FIG. 24(a) and FIG. 24(b) are sectional views for explaining a breaking process in the manufacture of the semiconductor device.

The molding die 20 in this embodiment 2 has a structure basically same as that in the embodiment 1, and the following structures are different from the embodiment 1.

Specifically, as shown in FIGS. 20 to 22, the molding die 20 in this embodiment 2 has a flow cavity 42 that extends along the other long side of the sealing cavity 29 (at the other long side 11b of the multi-wiring substrate 10) at this long side. The flow cavity 42 is, for example, provided at the upper die 20 and is made of recess section dented in the depth direction from the holding face a1 of the upper die 20a, although the structure is not limited thereto.

Plural runners (resin flowing path) 43 are arranged between the flow cavity 42 and the sealing cavity 29 along the other long side 11b of the multi-wiring substrate 10 (along the other long side 11b of the multi-wiring substrate 10). Each of the plural runners 43 crosses the other long side 11b of the multi-wiring substrate 10 and extends to the outside and inside of the multi-wiring substrate 10.

Each of the plural runners 42 is positioned at the outside of the other long side 11b of the multi-wiring substrate 10, and has a first portion 44 communicating with the flow cavity 42 and a second portion 45 positioned on the main surface 10x of the multi-wiring substrate 10 and communicating with the first portion 44 and the sealing cavity 29. The height 45h of the second portion 45 (the height from the main surface 10x of the multi-wiring substrate 10) is lower than the height 44h of the first portion 44 (the height from the main surface 10x of the multi-wiring substrate 10), and further lower than the height 29h of the sealing cavity 29. In this embodiment 2, the height 44h of the first portion 44 is set equal to the height (the height from the main surface 10x of the multi-wiring substrate 10) of the flow cavity 42.

Plural flow cavities 42 are arranged at one long side of the flow cavity 42, while plural air vents 31 are arranged along the other long side thereof. Each of the plural air vents communicates with the flow cavity 42.

The molding die 20 thus configured is used. As shown in FIGS. 20 to 22, the multi-wiring substrate 10 is positioned and clamped between the upper die 20a and the lower die 20b of the molding die 20, and then, thermosetting resin is injected into the sealing cavity 29 through the pot 21, cull 22, runner 23, and resin injection gate 28, whereby the resin sealing member 29a that seals plural semiconductor chips 2 mounted on the multi-wiring substrate 10 together at a time is formed.

Since the thermosetting resin is injected into the sealing cavity 29 through the pot 21, cull 22, runner 23, and resin injection gate 28 of the molding die 20 during this resin sealing process, a resin member (unnecessary resin member) 32 is formed, as shown in FIG. 23, from the thermosetting resin remaining on the cull 22, runner 23, or the like, separate from the resin sealing member 29a formed at the sealing cavity 29.

Further, the thermosetting resin is injected into the flow cavity 42 that is opposite to the runner 23 during this process, so that a resin member (unnecessary resin member) 46 integrated with the resin sealing member 29a is formed from the thermosetting resin injected into the flow cavity 42 and the runner 43.

The resin member 46 will be explained.

Since the resin member 46 is formed from the thermosetting resin remaining on the runner 43, flow cavity 42 or the like of the molding die 20, it is made into the shape generally same as that of the runner 43 and the flow cavity 42. Therefore, the resin member 46 is integrally formed with the resin sealing member 29a so as to cross the other long side 11b of the multi-wiring substrate 10 from the outside of the other long side 11b.

The resin member 46 is composed of a first resin portion 42a corresponding to the flow cavity 42 of the molding die 20, a second resin portion 44a corresponding to the first portion 44 of the runner 43 of the molding die 20, and a third resin portion 45a corresponding to the second portion 45 of the runner 43 of the molding die 20. The first and second resin portions (42a, 44a) are positioned at the outside of the multi-wiring substrate 10, wherein the second resin portion 44a communicates with the first resin portion 42a. The third resin portion 45a is positioned on the main surface 10x of the multi-wiring substrate 10 and communicates with the second resin portion 44a and the resin sealing member 29a.

The thickness (the thickness from the main surface 10x of the multi-wiring substrate 10) of the third resin portion 45a is thinner than the thickness (the thickness from the main surface 10x of the multi-wiring substrate 10) of the second resin portion 44a, and further, thinner than the thickness (the thickness from the main surface 10x of the multi-wiring substrate 10) of the resin sealing member 29a. The thickness of the first resin portion 42a (the thickness from the main surface 10x of the multi-wiring substrate 10) is equal to the thickness of the second resin portion 44a.

The second and third resin portions (44a, 45a) of the resin member 46 extend along the direction crossing the other long side 11b of the multi-wiring substrate 10, and the third resin portion 45a terminates at the other long side 11b of the multi-wiring substrate 10.

In the resin member 46 thus configured, the thickness of the third resin portion 45a adhered to the main surface 10x of the multi-wiring substrate 10 is thinner than the height of the first and second resin portions (42a, 44a) positioned at the outside of the multi-wiring substrate 10, and further, the third resin portion 45a terminates at the other long side 11b of the multi-wiring substrate 10. Therefore, when the resin member 46 is bent in the thickness direction of the multi-wiring substrate 10 with respect to the resin sealing member 29a, bending stress is concentrated on the joint section (separation section 46p) between the second resin portion 44a and the third resin portion 45a, with the result that a crack can be produced on the separation section 46p.

In the breaking process, the multi-wiring substrate 10 placed on the stage 35 is fixed by the package holding member 36 as shown in FIG. 24(a), and then, the resin member 32 is bent in the thickness direction of the multi-wiring substrate 10 with respect to the resin sealing member 29a such that bending stress is concentrated on the separation portion 32p of the resin member 32, resulting in that a crack is produced on the separation portion 32p. Further, the resin member 46 is bent in the thickness direction of the multi-wiring substrate 10 with respect to the resin sealing member 29a such that bending stress is concentrated on the separation portion 46p of the resin member 46, resulting in that a crack is produced on the separation portion 46p. Thus, as shown in FIG. 24(b), the resin member 32 is separated at the separation portion 32p, so that the first and second resin portions (32a, 32b) positioned at the outside of the multi-wiring substrate 10 can be removed. Further, the resin member 46 is separated at the separation portion 46p, so that the first and second resin portions (42a, 44a) positioned at the outside of the multi-wiring substrate 10 can be removed.

Thereafter, the processes same as those of the above-mentioned embodiment 1 are performed to almost complete the semiconductor device.

By using the molding die 20 provided with the flow cavity 42 as described above, non-filling of the thermosetting resin in the sealing cavity 29 can be prevented. Accordingly, poor molding of the resin sealing member 29a can be prevented, and further, the effects same as those in the embodiment 1 can be obtained.

### Embodiment 3

In the embodiment 3, a semiconductor device using a discrete molding method will be explained.

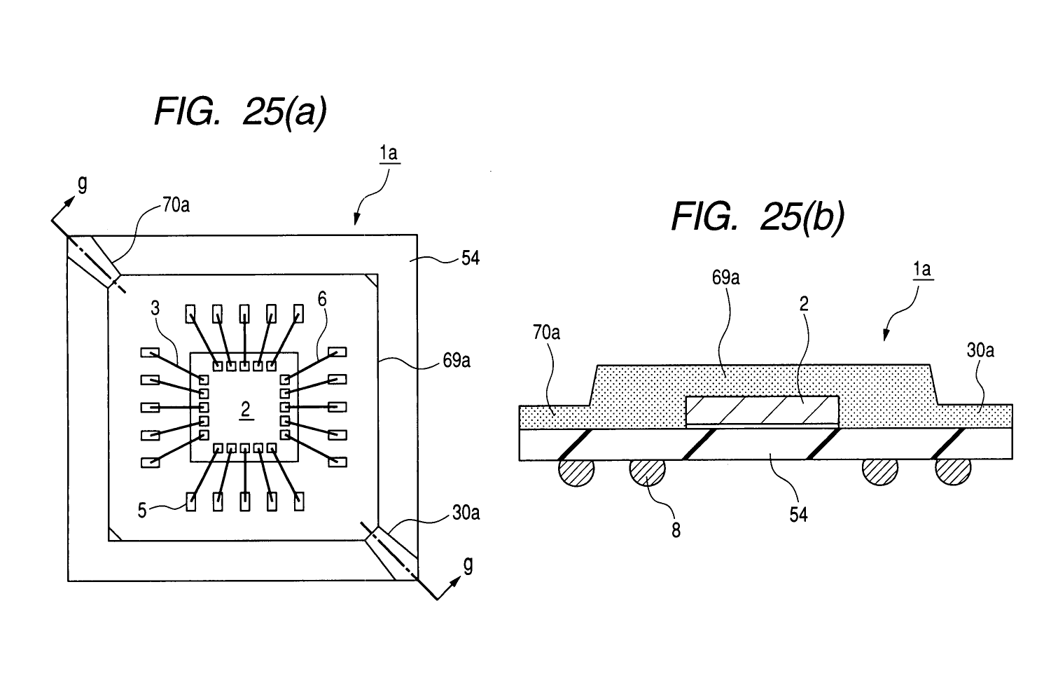

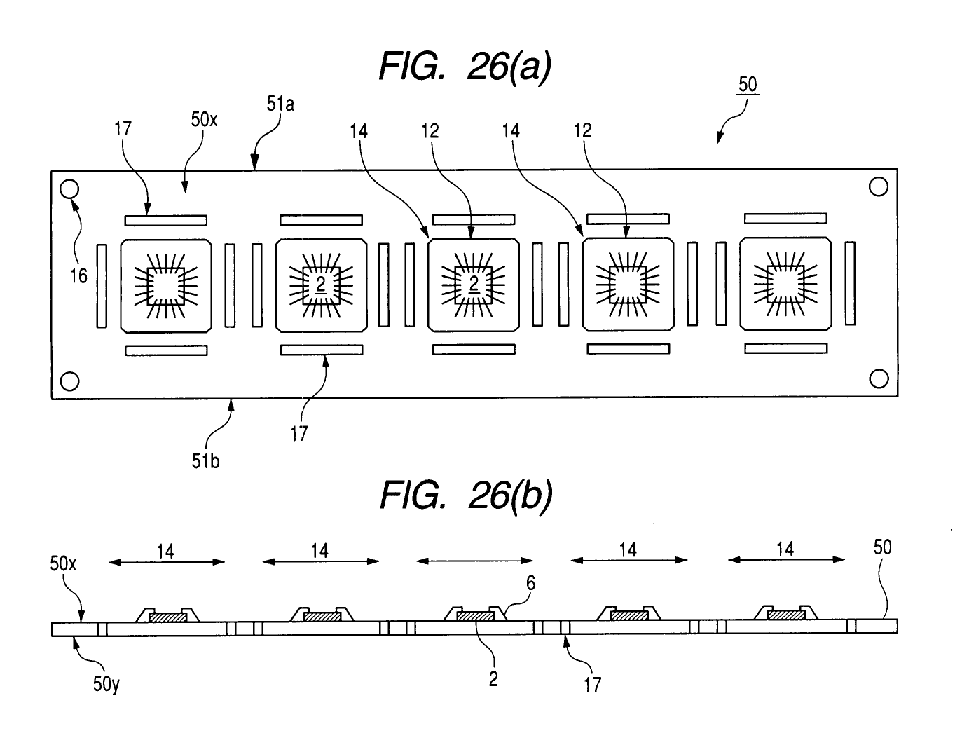

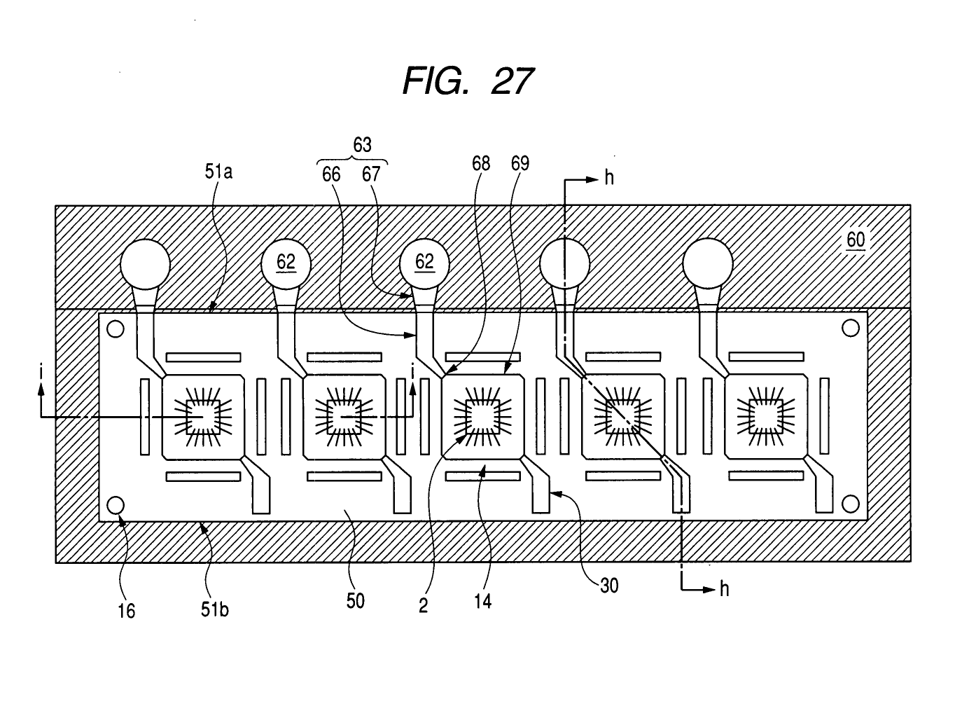

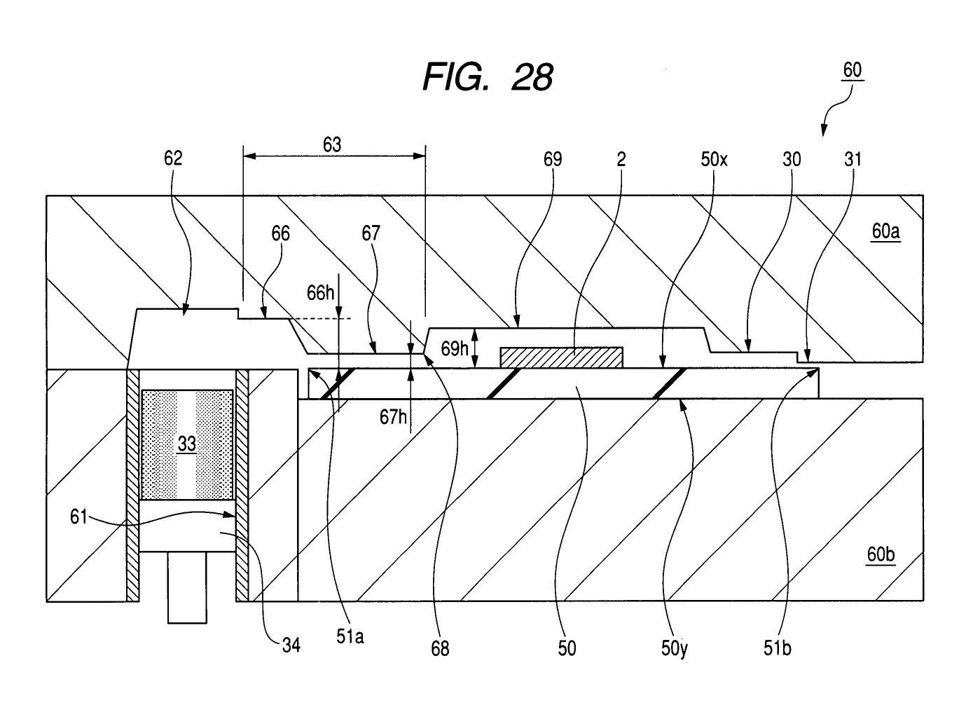

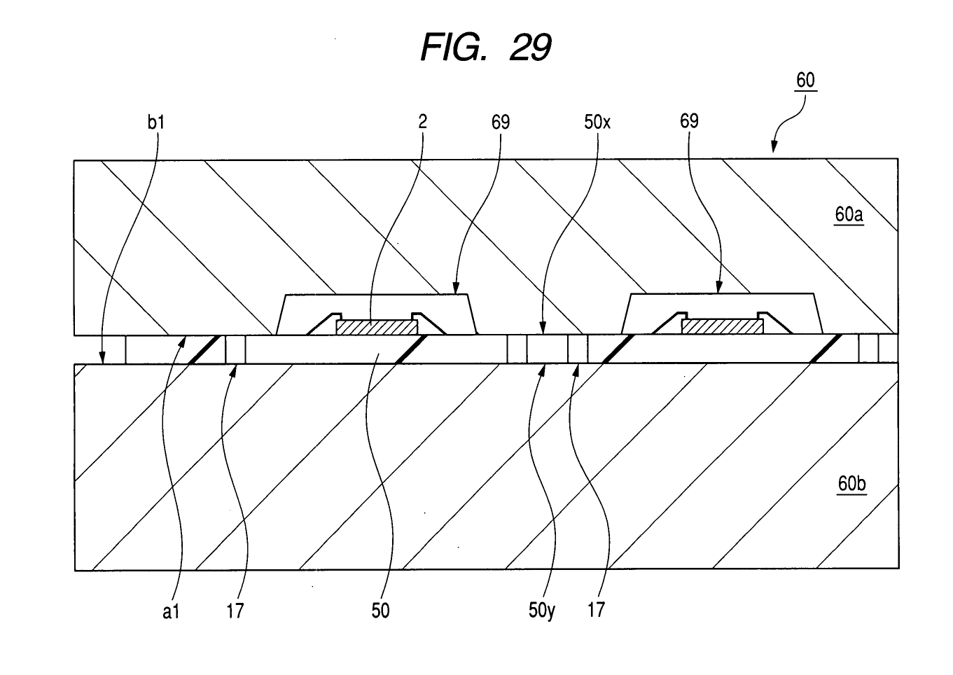

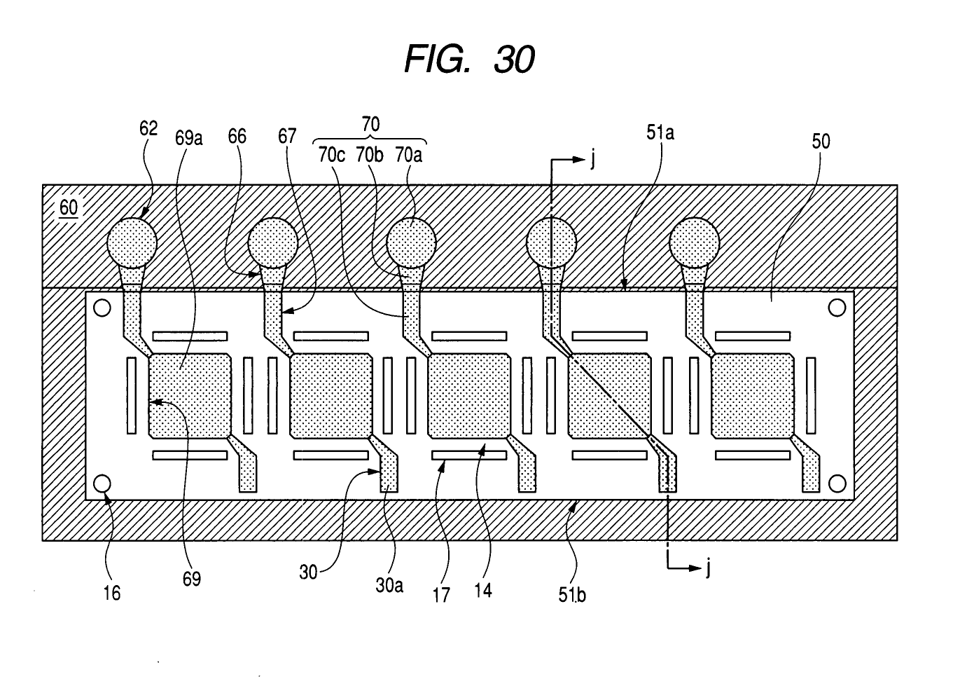

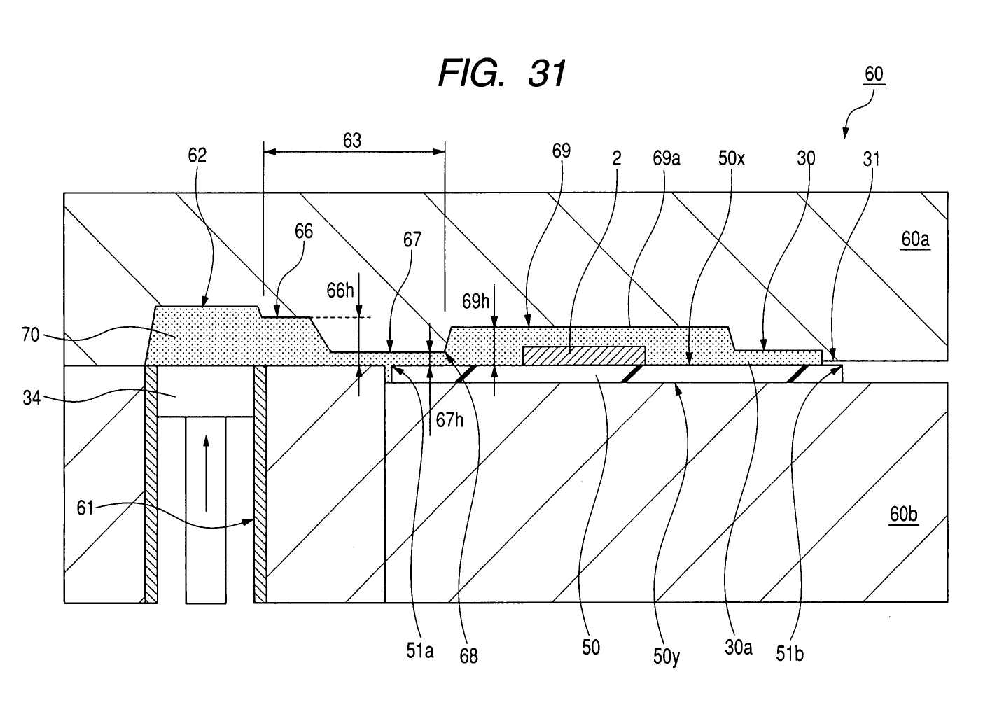

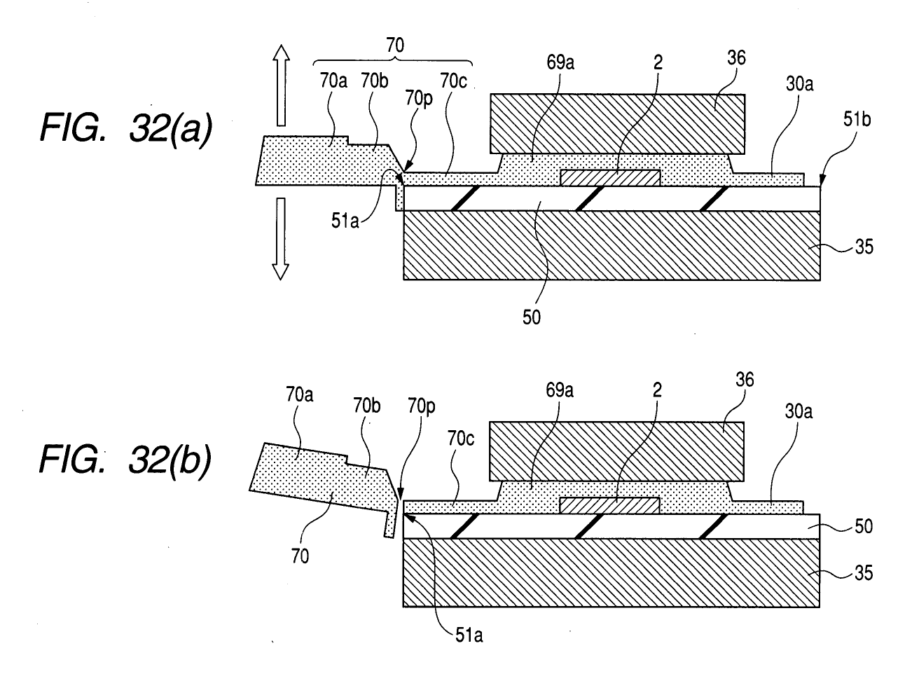

FIGS. 25 to 32 are views relating to the semiconductor device according to the embodiment 3, wherein FIG. 25(a) and FIG. 25(b) are views showing an internal structure of the semiconductor device, in which FIG. 25(a) is a perspective plan view and FIG. 25(b) is a sectional view taken along a line g-g in FIG. 25(a); FIG. 26(a) and FIG. 26(b) are views showing a configuration of a multi-wiring substrate used for manufacturing the semiconductor device, in which FIG. 26(a) is a plan view and FIG. 26(b) is a sectional view; FIG. 27 is a perspective plan view showing a state in which the multi-wiring substrate is clamped by a molding die in the manufacture of the semiconductor device; FIG. 28 is a sectional view taken along a line h-h in FIG. 27; FIG. 29 is a sectional view taken along a line i-i in FIG. 27; FIG. 30 is a perspective plan view showing a state in which resin is injected into a sealing cavity (resin sealing member forming section) of the molding die to form a resin sealing member in the manufacture of the semiconductor device; FIG. 31 is a sectional view taken along a line j-j in FIG. 30; and FIG. 32(a) and FIG. 32(b) are sectional views for explaining a breaking process in the manufacture of the semiconductor device.

As shown in FIGS. 25(a) and 25(b), a semiconductor device 1a according to the embodiment 3 has a package structure in which a semiconductor chip 2 is mounted on a main surface 54x of a wiring substrate 54 and plural ball-shaped soldering bumps 8, for example, are arranged as a projecting electrode on the back surf ace 54y that is opposite to the main surface 54x of the wiring substrate 54.

The semiconductor chip 2, plural bonding wires 6, and the like are sealed by a resin sealing member 7 selectively formed at the main surface 54x of the wiring substrate 54. The planar size of the resin sealing member 7 in this embodiment 3 is slightly smaller than the planar size of the wiring substrate 54.

As for two opposite corners of the resin sealing member 7, a resin member 70a that is integrally formed with the resin sealing member 7 is arranged at the outside of one corner, while a resin member 30a integrally formed with the resin sealing member 7 is arranged at the outside of the other corner. The resin members 70a and 30a are arranged on the main surface 54x of the wiring substrate 54.

A multi-wiring substrate 50 shown in FIGS. 26(a) and 26(b) and a molding die 60 shown in FIGS. 27 to 29 are used in the manufacture of the semiconductor device 1a.

As shown in FIGS. 26(a) and (b), a planar shape of the multi-wiring substrate 50 intersecting its thickness direction is quadrangular, e.g., rectangular in this embodiment. A plurality of device forming regions 14 are formed in one row on the main surface (chip mounting surface) of the multi-wiring substrate 50, and a molding region 12 is provided in each device forming region 14. Each of the device forming regions 14 are surrounded by four slits 17 corresponding to its four sides and provided at the outside of the device forming region 14. In this embodiment 3, the multi-wiring substrate 50 has, for example, five device forming regions 14 arranged in a row along its long side, although the structure is not limited thereto.

As shown in FIGS. 27 to 29, the molding die 60 has the upper die 60a and lower die 60b that are overlapped in the vertical direction (Z-direction), pot 61, cull 62, runner (resin flowing path) 63, resin injection gate 68, sealing cavity (resin sealing member forming section) 69, runner 30, and air vent section 31. The multi-wiring substrate 50 is arranged between the holding surface (mating face) a1 of the upper die 60a and the holding surface b1 of the lower die 60b as shown in FIG. 29, whereby it is fixedly held by clamping force exerted when the upper die 60a and the lower die 60b are clamped.

As shown in FIG. 28, the cull 62, runner (resin flowing path) 63, resin injection gate 68, sealing cavity (resin sealing member forming section) 69, runner (resin flowing path) 30, and air vent section 31 are formed at the upper die 60a, wherein these are made of recess sections dented in the depth direction from the holding face a1 of the upper die 60a, although the structure is not limited thereto. The pot 61 is provided at the lower die 60b, for example, although the structure is not limited thereto.

As shown in FIGS. 27 and 29, the sealing cavity 69 is positioned on the main surface 50x of the multi-wiring substrate 50 when the multi-wiring substrate 50 is positioned and clamped by the molding die 60. Plural sealing cavities 69 are provided so as to correspond to the respective device forming regions 14. The planar shape of the sealing cavity 69 is, for example, a square.

Plural pots 61, culls 62, runners 63, resin injection gates 68, runners (resin flowing path) 30 and air vents 31 are formed so as to correspond to the plural sealing cavities 69.

Each of the plural culls 62 is positioned at the outside of one long side 51a of two opposite long sides (51a, 51b) of the multi-wiring substrate 50 along one long side 51a.

The runner 63 is positioned between the corresponding cull 62 and the sealing cavity 69, and crosses one long side 51a of the multi-wiring substrate 50. One end of the runner 63 communicates with the corresponding cull 62, while the other end thereof communicates with the first corner of the corresponding sealing cavity 69.

The resin injection gate 68 is provided at the joint section between the runner 63 and the second corner of the sealing cavity 69.

Each runner 30 is positioned at the outside of the other long side 51b of the multi-wiring substrate 50 and arranged on the main surface 50x of the multi-wiring substrate 50. One end of the runner 30 communicates with the second corner of the sealing cavity 69 that is opposite to the first corner, while the other end thereof terminates at the position inward from the other long side 51b of the multi-wiring substrate 50.

Each air bent 31 communicates with the other end of the corresponding runner 30. Each pot 61 is arranged at the position overlapping with the corresponding cull 62.

As shown in FIGS. 27 and 28, the runner 63 has a first portion 66 positioned at the outside of the multi-wiring substrate 50 and a second portion 67 that communicates with the first portion 66 and the first corner of the sealing cavity 69 and is positioned on the main surface 50x of the multi-wiring substrate 50. As shown in FIG. 28, the height (the height from the main surface 50x of the multi-wiring substrate 50) 67h of the second portion 67 is lower than the height (the height from the main surface 50x of the multi-wiring substrate 50) 66h of the first portion 66, and further lower than the height (the height from the main surface 50x of the multi-wiring substrate 50) 69h of the sealing cavity 69. In this embodiment 3, the height 67h of the second portion 67 of the runner 63 is, for example, made equal to the height (the height from the main surface 50x of the multi-wiring substrate 50) of the resin injection gate 68.

The height 30h of the runner 30 from the main surface 50x of the multi-wiring substrate 50 is lower than the height 69h of the sealing cavity 69. In this embodiment 3, the height 30h of the runner 30 is set equal to the height 67h of the second portion 67 of the runner 30, for example.

Subsequently, the manufacture of the semiconductor device 1a will be explained with reference to FIGS. 26 to 32.

Firstly, the multi-wiring substrate 50 and the molding die 60 are prepared.

Then, as shown in FIGS. 26(a) and 26(b), semiconductor chips 2 are fixedly bonded to the respective chip mounting regions in the plural device forming regions 14 of the multi-wiring substrate 50 via an adhesive. Subsequently at the device forming regions 14 of the multi-wiring substrate 50, as shown in FIGS. 26(a) and 26(b), the plural connecting pads 5 (see FIG. 25(a)) of the device forming regions 14 and the plural connecting pads 3 (see FIG. 25(a)) of the semiconductor chips 2 mounted on the device forming regions 14 are electrically connected with plural bonding wires 6. By this process, plural semiconductor chips 2 are mounted over the main surface of the multi-wiring substrate 50 so as to correspond to the plural device forming regions 14.

Then, as shown in FIGS. 27 to 29, the multi-wiring substrate 50 is positioned and clamped between the upper die 60a and the lower die 60b of the molding die 60. In this case, the multi-wiring substrate 50 is positioned by inserting pilot pins of the molding die 60 into the positioning holes 16 of the multi-wiring substrate 50. The multi-wiring substrate 50 is fixedly held by clamping force caused when the upper die 60a and the lower die 60b are clamped.

Before the upper die 60a and the lower die 60b are clamped, resin tablet 33 heated in advance is put into each pot 61.

Subsequently, the molding die 60 is heated to melt the resin tablet 33 for raising the plunger 34 in the pot 61. As shown in FIGS. 30 and 31, the melted thermosetting resin is injected into the sealing cavity 69 through the pot 61, cull 62, runner 63, and resin injection gate 68 by the pressure due to the rise of the plunger 34. The plural semiconductor chips 2 mounted on the main surface 50x of the multi-wiring substrate 50 so as to correspond to each of the plural device forming regions 14 of the multi-wiring substrate 50 are sealed with the thermosetting resin injected into the sealing cavity 69. The resin sealing member 69a is formed in each of the sealing cavities 69 by curing the thermosetting resin that seals the semiconductor chips 2.

Since the thermosetting resin is injected into the sealing cavity 69 through the pot 61, cull 62, runner 63, and resin injection gate 68 of the molding die 60 during this resin sealing process, a resin member (unnecessary resin member) 70 is formed from the thermosetting resin remaining on the cull 62, runner 63, or the like, separate from the resin sealing member 69a formed at the sealing cavity 69. This resin member 70 is integrally formed with the resin sealing member 69a.

Further, the thermosetting resin is injected into the runner 30 that is opposite to the runner 63 during this process, so that a resin member (unnecessary resin member) 30a integrated with the resin sealing member 69a is formed from the thermosetting resin injected into the runner 30.

Then, a curing process is performed for stabilizing the cure of the resin sealing member 69a, and then, the molding die is opened to remove the multi-wiring substrate 50 from the molding die 60.

The resin members 70 and 30a will be explained.

Since the resin member 70 is formed from the thermosetting resin remaining on the cull 62, runner 63, or the like of the molding die 60, it is made into the shape generally same as that of the cull 62 or runner 63. Therefore, the resin member 70 is integrally formed with the resin sealing member 69a so as to cross one long side 51a of the multi-wiring substrate 50 from the outside of the long side 51a.

The resin member 70 is composed of a first resin portion 70a corresponding to the cull 62 of the molding die 60, a second resin portion 70b corresponding to the first portion 66 of the runner 63 of the molding die 60, and a third resin portion 70c corresponding to the second portion 67 of the sub-runner 63 of the molding die 60. The first and second resin portions (70a, 70b) are positioned at the outside of the multi-wiring substrate 50, wherein the second resin portion 70b communicates with the first resin portion 70a. The third resin portion 70c is positioned on the main surface 50x of the multi-wiring substrate 50 and communicates with the second resin portion 70b and the resin sealing member 69a.

The thickness (the thickness from the main surface 50x of the multi-wiring substrate 50) of the third resin portion 70c is thinner than the thickness (the thickness from the main surface 50x of the multi-wiring substrate 50) of the second resin portion 70b, and further, thinner than the thickness (the thickness from the main surface 50x of the multi-wiring substrate 50) of the resin sealing member 69a. The thickness (the thickness from the main surface 50x of the multi-wiring substrate 50) of the first resin portion 70a is thicker than the thickness of the second resin portion 70b.

The second and third resin portions (70b, 70c) of the resin member 70 extend along the direction crossing one long side 51a of the multi-wiring substrate 50, and the third resin portion 70c terminates at one long side 51a of the multi-wiring substrate 50.

In the resin member 70 thus configured, the thickness of the third resin portion 70c adhered to the main surface 50x of the multi-wiring substrate 50 is thinner than the thickness of the first and second resin portions (70a, 70b) positioned at the outside of the multi-wiring substrate 50, and further, the third resin portion 70c terminates at one long side 51a of the multi-wiring substrate 50. Therefore, when the resin member 70 is bent in the thickness direction of the multi-wiring substrate 50 with respect to the resin sealing member 69a, bending stress is concentrated on the joint section (separation section 70p) between the second resin portion 70b and the third resin portion 70c, with the result that a crack can be produced on the separation section 70p.

Since the resin member 30a is formed from the thermosetting resin remaining on the runner 30 of the molding die 60, it is made into the shape generally the same as that of the runner 30. Accordingly, the resin member 30a is formed on the main surface 50x of the multi-wiring substrate 50 at the other long side 51b thereof. Further, the resin member 30a has one end communicating with the resin sealing member 69a and the other end terminating at the inside of the other long side 51b of the multi-wiring substrate 50. The thickness of the resin member 30a from the main surface 50x of the multi-wiring substrate 50 is thinner than the thickness of the resin sealing member 69a. In this embodiment 3, the thickness of the resin member 30a is set equal to the thickness of the third resin portion 70c of the resin member 70, for example.

Subsequently, as shown in FIG. 32(a), the multi-wiring substrate 50 arranged on the stage 35 is fixed by the package holding member 36, and then, the resin member 70 is bent in the thickness direction of the multi-wiring substrate 50 with respect to the resin sealing member 69a such that bending stress is concentrated on the separation section 70p of the resin member 70, thereby producing a crack on the separation section 70p. Thus, as shown in FIG. 32(b), the resin member 70 is separated at the separation section 70p, whereby the first and second resin portions (70a, 70b) of the resin member 70 positioned at the outside of the multi-wiring substrate 50 are removed.

Then, the processes same as those in the above-mentioned embodiment 1 are performed, thereby almost completing the semiconductor device 1a shown in FIGS. 25(a) and 25(b).

As described above, the effects same as those in the embodiment 1 can be obtained even from the embodiment 3.

The invention made by the inventors was specifically explained above with reference to the embodiments. The present invention is not limited to the aforesaid embodiments. Various modifications are of course possible without departing from the spirit of the present invention.

For example, the present invention can be applied to a semiconductor device in which a semiconductor chip is mounted via a projecting electrode on a wiring substrate (flip-chip mounting).

1. A method of manufacturing a semiconductor device comprising the steps of:
preparing a wiring substrate having a semiconductor chip mounted over its main surface;
preparing, when the wiring substrate is arranged between an upper die and a lower die, a molding die having a resin sealing member forming section positioned over the main surface of the wiring substrate so as to cover the semiconductor chip mounted over the wiring substrate, and a resin flowing path crossing one side of the wiring substrate from the outside of the wiring substrate to communicate with the resin sealing member forming section;
forming a resin sealing member that resin-seals the semiconductor chip mounted over the wiring substrate, arranged between the upper die and the lower die of the molding die, by injecting resin into the resin sealing member forming section through the resin flowing path; and
applying bending stress to a resin member, that is formed integrally with the resin sealing member from the remaining resin in the resin flowing path, in the widthwise direction of the wiring substrate, thereby producing a crack on the resin member,
wherein the resin flowing path has a first portion positioned at the outside of the wiring substrate and a second portion communicating with the first portion and the resin sealing member forming section and positioned over the main surface of the wiring substrate, and
wherein the height of the second portion from the main surface of the wiring substrate is lower than that of the first portion.

2. A method of manufacturing a semiconductor device according to claim 1, wherein the height of the second portion of the resin flowing path from the main surface of the wiring substrate is lower than that of the resin sealing member forming section.

3. A method of manufacturing a semiconductor device according to claim 1, wherein the second portion of the resin flowing path terminates at one side of the wiring substrate.

4. A method of manufacturing a semiconductor device according to claim 1, wherein the second portion of the resin flowing path terminates at the vicinity of one side of the wiring substrate over the main surface of the wiring substrate.

5. A method of manufacturing a semiconductor device according to claim 1, wherein the first portion and the second portion of the resin flowing path communicate with each other over one side of the wiring substrate.

6. A method of manufacturing a semiconductor device according to claim 1, wherein the first portion and the second portion of the resin flowing path communicate with each other at the position slightly inward of one side of the wiring substrate.

7. A method of manufacturing a semiconductor device according to claim 1, wherein the height of the second portion of the resin flowing path from the main surface of the wiring substrate is equal to a resin injection gate at the joint section between the second portion and the resin sealing member forming section.

8. A method of manufacturing a semiconductor device according to claim 1, wherein the height of the second portion of the resin flowing path from the main surface of the wiring substrate is higher than a resin injection gate at the joint section between the second portion and the resin sealing member forming section.

9. A method of manufacturing a semiconductor device according to claim 1, wherein the step of forming the resin sealing member is performed in a state in which a film is adhered onto the inner face of the resin flowing path and the inner face of the resin sealing member forming section.

10. A method of manufacturing a semiconductor device according to claim 1,
wherein the wiring substrate has plural device forming regions,
wherein plural semiconductor chips are mounted so as to correspond to each of the device forming regions of the wiring substrate,
wherein plural resin flowing paths are provided along one side of the wiring substrate, and
wherein the resin sealing member forming section is formed to have a size collectively covering the plural device forming regions over the wiring substrate.

11. A method of manufacturing a semiconductor device according to claim 1,
wherein the wiring substrate has plural device forming regions along one side thereof,
wherein plural semiconductor chips are mounted so as to correspond to each of the device forming regions of the wiring substrate, and
wherein plural resin flowing paths and plural resin sealing member forming sections are provided so as to correspond to each of the plural device forming regions over the wiring substrate.

12. A method of manufacturing a semiconductor device comprising the steps of:
preparing a wiring substrate having a semiconductor chip mounted over its main surface;
preparing, when the wiring substrate is arranged between an upper die and a lower die, a molding die having a resin sealing member forming section positioned over the main surface of the wiring substrate so as to cover the semiconductor chip mounted over the wiring substrate, a first resin flowing path crossing a first side of the wiring substrate from the outside of the wiring substrate to communicate with the resin sealing member forming section, and a second resin flowing path positioned over the main surface of the wiring substrate at a second side of the wiring substrate that is opposite to the first side thereof to communicate with the resin sealing member forming section;
forming a resin sealing member that resin-seals the semiconductor chip mounted over the wiring substrate, arranged between the upper die and the lower die of the molding die, and a second resin member integrally formed with the resin sealing member, by injecting resin into the resin sealing member forming section through the first resin flowing path and into the second resin flowing path; and
applying bending stress to a first resin member, that is formed integrally with the resin sealing member by the remaining resin in the first resin flowing path, in the widthwise direction of the wiring substrate, thereby producing a crack on the first resin member,
wherein the first resin flowing path of the molding die has a first portion positioned at the outside of the wiring substrate and a second portion communicating with the first portion and the resin sealing member forming section and positioned over the main surface of the wiring substrate, and
wherein the height of the second portion of the first resin flowing path and the height of the second resin flowing path from the main surface of the wiring substrate are lower than that of the first portion of the first resin flowing path and that of the resin sealing member forming section.

13. A manufacturing method of a semiconductor device according to claim 12,
wherein one end of the second resin flowing path communicates with the resin sealing member forming section, and
wherein the other end of the second resin flowing path terminates at the position inward of the second side of the wiring substrate.

14. A manufacturing method of a semiconductor device according to claim 13, wherein the other end of the second resin flowing path communicates with an air bent.

15. A manufacturing method of a semiconductor device according to claim 12, wherein the step of forming the resin sealing member is performed in a state in which a film is adhered onto the inner faces of the first and second resin flowing paths and the inner face of the resin sealing member forming section.

16. A manufacturing method of a semiconductor device according to claim 12,
wherein the wiring substrate has plural device forming regions,
wherein plural semiconductor chips are mounted so as to correspond to each of the device forming regions of the wiring substrate,
wherein plural first resin flowing paths are provided along the first side of the wiring substrate,
wherein plural second resin flowing paths are provided along the second side of the wiring substrate, and
wherein the resin sealing member forming section is formed to have a size collectively covering the plural device forming regions over the wiring substrate.

17. A manufacturing method of a semiconductor device according to claim 12,
wherein the wiring substrate has plural device forming regions along the first side of the wiring substrate,
wherein plural semiconductor chips are mounted so as to correspond to each of the device forming regions of the wiring substrate, and
wherein plural first and second resin flowing paths and plural resin sealing member forming sections are provided so as to correspond to each of the plural device forming regions.

18.-25. (canceled)
